(19) United States
(12) Patent Application Publication
(10) Pub. No.: US 2025/0113634 A1
(43) Pub. Date: Apr. 3, 2025

(54) SEMICONDUCTOR DEVICE, ELECTRONIC DEVICE, AND METHOD FOR MANUFACTURING SEMICONDUCTOR DEVICE

(71) Applicant: SONY SEMICONDUCTOR SOLUTIONS CORPORATION, KANAGAWA (JP)

(72) Inventor: ATSUSHI TSUKADA, KANAGAWA (JP)

(21) Appl. No.: 18/727,754

(22) PCT Filed: Dec. 28, 2022
(86) PCT No.: PCT/JP2022/048692

§ 371 Date: Jul. 10, 2024

(30) Foreign Application Priority Data
Jan. 21, 2022 (JP) 2022-008073

(51) Int. Cl. H10F 39/00; H10F 39/18

(52) U.S. Cl. CPC H10F 39/804; H10F 39/014; H10F 39/182; H10F 39/811

(57) ABSTRACT

Provided is a semiconductor device capable of improving thermal conductivity from a semiconductor element to a substrate side, and capable of stabilizing heat dissipation characteristics. The semiconductor device includes a substrate, a semiconductor element provided on the substrate, and a heat transfer member that has fluidity and that fills a space part between the substrate and the semiconductor element. One or more in-substrate cavity parts that communicate with the space part at one end and receive the heat transfer member are formed in the substrate.

### TECHNICAL FIELD

The present disclosure relates to a semiconductor device, an electronic device, and a method for manufacturing a semiconductor device.

### BACKGROUND ART

Conventional semiconductor devices that include semiconductor elements (semiconductor chips), such as image sensors including CMOS image sensors, logic ICs having predetermined circuit structures, or light-emitting elements such as semiconductor lasers, have a configuration in which the semiconductor element is bonded to a substrate, such as an organic substrate or a ceramic substrate, using a die-bonding material that forms an adhesive layer. The semiconductor element is electrically connected to the substrate by connection members such as bonding wires. In a configuration in which an image sensor is provided as the semiconductor element, a transparent member such as glass is provided to the substrate above the image sensor over a frame-shaped support member or the like (see PTL 1, for example).

With regard to a die-bonding material disposed on a rear surface side of the semiconductor element as an adhesive part for the substrate, from the standpoint of reducing warpage and distortion (incline) of the semiconductor chip, a configuration is adopted in which the die-bonding material is disposed in parts of the rear surface of the semiconductor chip, rather than over the entirety thereof. Specifically, a configuration in which the die-bonding material is disposed on the rear surface of the semiconductor chip, at a peripheral edge of the semiconductor chip that follows the outer shape of the rectangular chip, is generally used.

### CITATION LIST

### Patent Literature

### [PTL 1]

JP 2012-217021A

### SUMMARY

### Technical Problem

In a configuration where a die-bonding material is disposed on the rear surface of the semiconductor chip at the peripheral edge of the chip as mentioned above, the die-bonding material is disposed so as to form a rectangular frame shape in plan view. Accordingly, a cavity surrounded by the die-bonding material is present between the substrate and the semiconductor element, i.e., on the rear surface side of the semiconductor element. In such a configuration, heat produced by the semiconductor element during operation is conducted to the substrate side through the die-bonding material.

In other words, in a configuration such as that described above, because a cavity is present on the rear surface side of the semiconductor element, heat from the semiconductor element is conducted directly to the substrate side only from the die-bonding material that is in partial contact with the rear surface of the semiconductor element. Accordingly, with this semiconductor element, it is difficult to achieve sufficient heat dissipation performance at parts such as those which are not in contact with the die-bonding material on the rear surface side. There is thus a problem in that it is difficult to achieve good thermal conductivity from the semiconductor element to the substrate side.

An object of the present technique is to provide a semiconductor device, an electronic device, and a method for manufacturing a semiconductor device capable of improving thermal conductivity from a semiconductor element to a substrate side, and capable of stabilizing heat dissipation characteristics.

### Solution to Problem

A semiconductor device according to the present technique includes a substrate, a semiconductor element provided on the substrate, and a heat transfer member that has fluidity and that fills a space part between the substrate and the semiconductor element. One or more in-substrate cavity parts that communicate with the space part at one end and receive the heat transfer member are formed in the substrate.

In another aspect of the semiconductor device according to the present technique, in the semiconductor device, the in-substrate cavity part is formed such that an other end is open toward a surface of the substrate, and a blocking part that blocks the other end of the in-substrate cavity part is provided on a surface side of the substrate.

In another aspect of the semiconductor device according to the present technique, in the semiconductor device, the blocking part is a support member for supporting a transparent member provided for the semiconductor element on the substrate, or a joining part that joins the transparent member to the surface of the substrate.

In another aspect of the semiconductor device according to the present technique, the semiconductor device further includes a sealing resin part formed on the substrate in a periphery of the semiconductor element, and the blocking part is the sealing resin part.

In another aspect of the semiconductor device according to the present technique, in the semiconductor device, the in-substrate cavity part has a channel part having a relatively small flow channel area, and a containment part that communicates with the channel part and has a larger flow channel area than the channel part.

In another aspect of the semiconductor device according to the present technique, in the semiconductor device, the in-substrate cavity part is formed having an uneven shape when the substrate is viewed in a side cross-sectional view.

In another aspect of the semiconductor device according to the present technique, in the semiconductor device, the in-substrate cavity part has an expanded part that is open toward the surface of the substrate at an end part of the other end.

In another aspect of the semiconductor device according to the present technique, the semiconductor device further includes a support part that supports the semiconductor element on the substrate and forms the space part together with the substrate and the semiconductor element, and the substrate has a protrusion that is provided along an inner side of the support part and that protrudes from the surface of the substrate.

In another aspect of the semiconductor device according to the present technique, in the semiconductor device, the protrusion is provided as a part of the substrate.

An electronic device according to the present technique includes a semiconductor device, the semiconductor device including a substrate, a semiconductor element provided on the substrate, and a heat transfer member that has fluidity and that fills a space part between the substrate and the semiconductor element. One or more in-substrate cavity parts that communicate with the space part at one end and receive the heat transfer member are formed in the substrate.

A method for manufacturing a semiconductor device according to the present technique includes: providing, on a substrate having an in-substrate cavity part that has one end and an other end open toward a surface side, a die-bonding material serving as a support part that, together with the substrate and the semiconductor element provided on the substrate, forms a space part that communicates with the one end of the in-substrate cavity part, the die-bonding material having an endless shape in plan view; inserting a heat transfer member having fluidity into a space within the die-bonding material on the surface side of the substrate; and forming the space part by mounting the semiconductor element on the die-bonding material, and filling the space part with the heat transfer member.

The method for manufacturing a semiconductor device according to the present technique further includes blocking an opening on the other end of the in-substrate cavity part after the filling of the heat transfer member.

In the method for manufacturing a semiconductor device according to the present technique, the blocking of the opening on the other end is providing, on the substrate, a transparent member provided for the semiconductor element or a support member that supports the transparent member on the substrate.

In the method for manufacturing a semiconductor device according to the present technique, the blocking of the opening on the other end is providing a sealing resin part in a periphery of the semiconductor element on the substrate.

### BRIEF DESCRIPTION OF DRAWINGS

FIG. 1 is a side cross-sectional view illustrating the configuration of a semiconductor device according to a first embodiment of the present technique.

FIG. 2 is a planar cross-sectional view illustrating the configuration of the semiconductor device according to the first embodiment of the present technique.

FIG. 3 is an explanatory diagram illustrating a method for manufacturing the semiconductor device according to the first embodiment of the present technique.

FIG. 4 is an explanatory diagram illustrating a method for manufacturing the semiconductor device according to the first embodiment of the present technique.

FIG. 5 is a side cross-sectional view illustrating the configuration of a first variation on the semiconductor device according to the first embodiment of the present technique.

FIG. 6 is a side cross-sectional view illustrating the configuration of a second variation on the semiconductor device according to the first embodiment of the present technique.

FIG. 7 is an explanatory diagram illustrating a manufacturing method for the configuration of the second variation on the semiconductor device according to the first embodiment of the present technique.

FIG. 8 is a side cross-sectional view illustrating the configuration of a third variation on the semiconductor device according to the first embodiment of the present technique.

FIG. 9 is a side cross-sectional view illustrating the configuration of a semiconductor device according to a second embodiment of the present technique.

FIG. 10 is an explanatory diagram illustrating a method for manufacturing the semiconductor device according to the second embodiment of the present technique.

FIG. 11 is an explanatory diagram illustrating a method for manufacturing the semiconductor device according to the second embodiment of the present technique.

FIG. 12 is a side cross-sectional view illustrating the configuration of a semiconductor device according to a third embodiment of the present technique.

FIG. 13 is a planar cross-sectional view illustrating the configuration of the semiconductor device according to the third embodiment of the present technique.

FIG. 14 is an explanatory diagram illustrating a method for manufacturing the semiconductor device according to the third embodiment of the present technique.

FIG. 15 is a side cross-sectional view illustrating the configuration of a semiconductor device according to a fourth embodiment of the present technique.

FIG. 16 is a block diagram illustrating an example of the configuration of an electronic device including a semiconductor device according to the embodiments of the present technique.

### DESCRIPTION OF EMBODIMENTS

The present technique attempts to improve the cooling efficiency of a semiconductor device by filling a space part on a rear surface side of a semiconductor element on a substrate with a heat transfer member (a heat transfer liquid).

Modes for carrying out the present technique (hereinafter referred to as “embodiments”) will be described hereinafter with reference to the drawings. Note that the drawings are schematic, and the dimensional ratios and the like of each part are not necessarily consistent with the actual ones. In addition, the drawings of course include parts where dimensional relationships and ratios differ from drawing to drawing. The embodiments will be described in the following order.
1. Example of Configuration of Semiconductor Device According to First Embodiment
2. Method for Manufacturing Semiconductor Device According to First Embodiment
3. Variations on Semiconductor Device According to First Embodiment
4. Example of Configuration of Semiconductor Device According to Second Embodiment
5. Method for Manufacturing Semiconductor Device According to Second Embodiment
6. Example of Configuration of Semiconductor Device According to Third Embodiment
7. Method for Manufacturing Semiconductor Device According to Third Embodiment
8. Example of Configuration of Semiconductor Device According to Fourth Embodiment
9. Example of Configuration of Electronic Device

### 1. Example of Configuration of Semiconductor Device According to First Embodiment

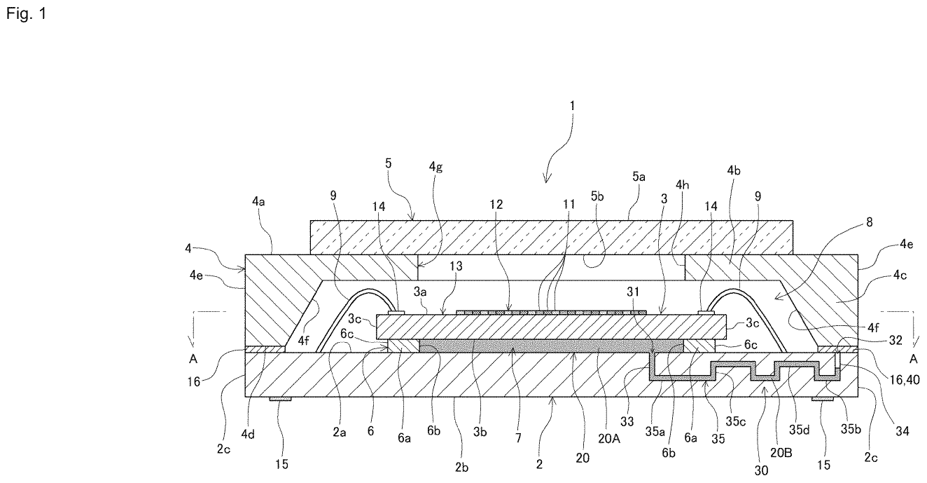

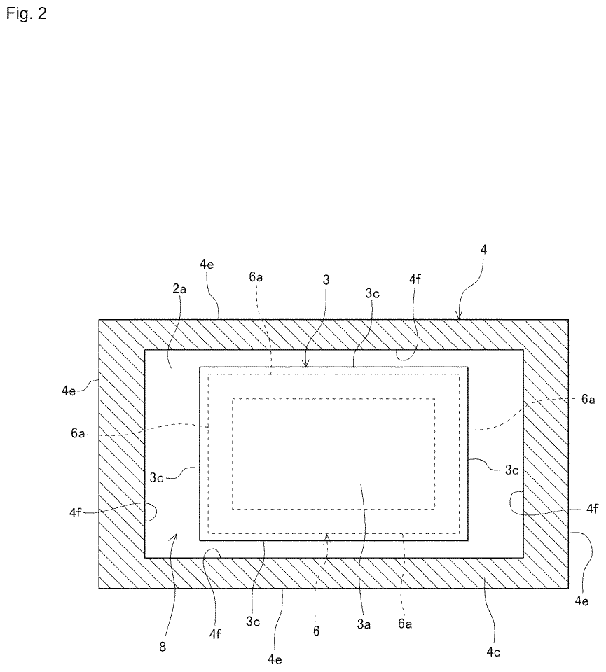

An example of the configuration of a semiconductor device according to a first embodiment of the present technique will be described with reference to FIGS. 1 and 2. The present embodiment will describe a solid-state image capturing device, including a solid-state image sensor as an example of a semiconductor element, as a semiconductor device. Note that the vertical direction in FIG. 1 is a vertical direction of a solid-state image capturing device 1. FIG. 2 is a cross-sectional view of a position A-A in FIG. 1, with some of the configurations omitted.

As illustrated in FIGS. 1 and 2, the solid-state image capturing device 1 includes a substrate 2, and an image sensor 3 as a solid-state image sensor provided on the substrate 2. The solid-state image capturing device 1 also includes a frame 4 as a support member provided on the substrate 2, and a glass 5 as a transparent member provided on the frame 4.

The image sensor 3 is attached to the substrate 2 by a die-bonding material 6, such as an insulative or conductive adhesive. In other words, the solid-state image capturing device 1 includes the die-bonding material 6 that supports the image sensor 3 with respect to the substrate 2. The die-bonding material 6 is a support part (element support part) that forms a space part 7 together with the substrate 2 and the image sensor 3.

The solid-state image capturing device 1 has a package structure in which the glass 5 is mounted on the substrate 2 using the frame 4, and a cavity 8 is formed as a hollow part between the image sensor 3 and the glass 5. In other words, the glass 5 is provided parallel with the image sensor 3 above the image sensor 3, and the cavity 8, which is a sealed space formed with the substrate 2, is formed above the substrate 2 by the frame 4 and the glass 5.

The substrate 2 is a flat plate-shaped member having a rectangular outer shape. The substrate 2 has a front surface 2a, which is a surface on which the image sensor 3 is mounted; a rear surface 2b, which is the surface on the side opposite the front surface 2a; and four side surfaces 2c. The image sensor 3 is die-bonded to the front surface 2a of the substrate 2 by the die-bonding material 6. In other words, the die-bonding material 6 provided on the front surface 2a of the substrate 2 supports the image sensor 3 so as to face the front surface 2a while being parallel to the substrate 2. A thickness direction of the substrate 2 is the vertical direction of the solid-state image capturing device 1, the front surface 2a side is an upper side, and the rear surface 2b side is a lower side.

The substrate 2 is a ceramic substrate formed using ceramics such as alumina (Al2O3), aluminum nitride (AlN), silicon nitride (Si3N4) or the like as a material, and is a circuit substrate on which a predetermined circuit pattern is formed from a metal material. However, the substrate 2 may be another type of substrate, such as an organic substrate using, as a base material, an organic material such as a glass epoxy resin, which is a type of fiber-reinforced plastic.

The image sensor 3 is a semiconductor element including a semiconductor substrate formed from silicon (Si), which is an example of a semiconductor. The image sensor 3 is a rectangular plate-shaped chip, where a front surface 3a side, which is the surface on the upper side, serves as a light-receiving surface side, and the surface on the opposite side serves as a rear surface 3b. The image sensor 3 has four side surfaces 3c. A plurality of light-receiving elements (photoelectric conversion elements) are formed on the front surface 3a side of the image sensor 3. The image sensor 3 is a Complementary Metal Oxide Semiconductor (CMOS)-type image sensor. However, the image sensor 3 may be another type of image sensor, such as a Charge Coupled Device (CCD)-type image sensor.

The image sensor 3 has, on the front surface 3a side, a pixel region 12 including a plurality of pixels 11 formed in a predetermined array, such as a Bayer array, as a light-receiving unit. A region in the periphery of the pixel region 12 is a peripheral region 13. Predetermined peripheral circuitry is formed in the peripheral region 13. Each of the pixels 11 includes a photodiode serving as a photoelectric conversion unit having a photoelectric conversion function, and a plurality of pixel transistors.

On the front surface 3a side of the image sensor 3, a color filter and an on-chip lens are formed corresponding to each pixel 11 on the semiconductor substrate, over an anti-reflection film constituted by an oxide film or the like, a planarizing film formed from an organic material, and the like. Light incident on the on-chip lens is received by the photodiode through the color filter, the planarizing film, and the like.

The configuration of the image sensor 3 according to the present technique is not particularly limited. Examples of the configuration of the image sensor 3 include a front side illumination type, in which the pixel region 12 is formed on the front surface side of the semiconductor substrate; a back side illumination type in which photodiodes or the like are conversely disposed to improve the transmittance of light, and the rear surface side of the semiconductor substrate serves as the light-receiving surface; and a single chip in which the peripheral circuitry of the pixels is stacked.

The die-bonding material 6 is partially interposed between the front surface 2a of the substrate 2 and the rear surface 3b of the image sensor 3, and by bonding the substrate 2 and the image sensor 3 with those parts spaced apart from each other, a gap-shaped space part 7, which is a sealed space, is formed between the substrate 2 and the image sensor 3. The die-bonding material 6 functions as a sealing part that hermetically seals the periphery of the space part 7 between the substrate 2 and the image sensor 3. In other words, the image sensor 3 is provided on the substrate 2 over the sealed space part 7.

The die-bonding material 6 is provided in a position corresponding to the peripheral region 13 of the image sensor 3 so as to surround the area where the pixel region 12 of the image sensor 3 is formed, in plan view. The die-bonding material 6 is provided over the entire periphery along the outer shape of the image sensor 3 in plan view, and is formed in an endless shape so as to create a rectangular frame in plan view. Accordingly, the die-bonding material 6 has four side parts 6a following corresponding sides of the rectangular outer shape of the image sensor 3.

The die-bonding material 6 is provided in a position within the range of the outer shape of the image sensor 3 so as to follow the outer edges of the image sensor 3 in plan view. The die-bonding material 6 is provided in a position slightly inward from the side surfaces 3c of the image sensor 3. However, the die-bonding material 6 may be provided such that outer side surfaces 6c thereof are substantially flush with the side surfaces 3c of the image sensor 3.

The die-bonding material 6 is formed from an insulating material. Specifically, the material from which the die-bonding material 6 is formed is, for example, a photosensitive adhesive such as an ultraviolet (UV)-curable resin, which is an acrylic resin, a thermosetting resin such as an epoxy resin, or a mixture thereof. The die-bonding material 6 is formed through application using a dispenser, patterning using photolithography, or the like on the front surface 2a of the substrate 2 or the rear surface 3b of the image sensor 3.

The die-bonding material 6 is an example of a support part according to the present technique, and the material and configuration of the support part according to the present technique are not limited to the present embodiment.

The support part according to the present technique may be a part provided by, for example, affixing a frame-shaped structure constituted by ceramics such as glass, an inorganic material such as metal or silicon, or the like to the substrate 2 and the image sensor 3 using an adhesive or the like.

The substrate 2 and the image sensor 3 are electrically connected by a plurality of bonding wires 9 serving as connection members. The bonding wires 9 are conductive wires, and are provided with a curved shape or a bent shape that is convex on the upper side, such as an arch shape, so as to span between the front surface 3a of the image sensor 3 and the front surface 2a of the substrate 2.

The bonding wires 9 are metal filaments formed from Au (gold), Cu (copper), Al (aluminum), or the like, for example. Each of the bonding wires 9 is connected at one end to an electrode (not shown) formed on the front surface 2a of the substrate 2, and at the other end to a pad electrode 14 formed on the front surface 3a of the image sensor 3, thereby electrically connecting these electrodes to each other. The plurality of bonding wires 9 are provided according to the number of pad electrodes 14. The pad electrode 14 is a terminal for sending and receiving signals to and from the outside of the image sensor 3, and is formed from an aluminum material or the like through plating or the like, for example. The pad electrode 14 is located above the die-bonding material 6, for example.

The electrodes of the substrate 2 to which the bonding wires 9 are connected are electrically connected to a plurality of terminal electrodes 15 formed on the rear surface 2b of the substrate 2 through a predetermined wiring part formed within the substrate 2. A solder ball serving as an external connection terminal is provided as each of the terminal electrodes 15, which forms a ball grid array (BGA).

The frame 4 is provided to surround the image sensor 3 on the front surface 2a side of the substrate 2. The frame 4 is an integral member constituted by a resin material such as an epoxy resin, a metal material such as stainless steel or copper (Cu), ceramics, or the like, for example. From the standpoint of preventing the reflection of light, the frame 4 is formed, for example, from a low-reflection black resin material in which a black pigment such as carbon black or titanium black is added to a resin such as a liquid crystal polymer or polyether ether ketone (PEEK), and is manufactured through a publicly-known method such as injection molding. Note that the frame 4 is not limited to one type of material as a whole, and may be a composite structure having a part constituted by a metal material and a part constituted by a resin material.

The frame 4 is a rectangular or square-shaped frame-shaped member which is larger than the outer shape of the image sensor 3 in plan view, and has approximately the same outer dimensions as the outer shape of the substrate 2 in plan view. The frame 4 has a plate-shaped upper surface part 4b that forms an upper surface 4a along a horizontal plane, and a peripheral wall part 4c formed on the lower side of the upper surface part 4b. The upper surface part 4b is provided parallel to the image sensor 3 at a position above the image sensor 3. The peripheral wall part 4c is formed over the entire periphery along the outer shape of the frame 4, at the outside edge of the frame 4. In the frame 4, a lower end surface of the peripheral wall part 4c is a lower surface 4d parallel to the horizontal plane.

The frame 4 has outer side surfaces 4e formed parallel to the vertical direction by the upper surface part 4b and the peripheral wall part 4c. The frame 4 is provided such that the four side surfaces 4e are flush with the side surfaces 2c of the substrate 2. Inner wall surfaces of the peripheral wall part 4c are inclined surfaces 4f inclined as the surface progresses from the outside to the inside (the center side of the plane) and from the lower side to the upper side, in a side cross-sectional view. In other words, the four inclined surfaces 4f are inclined along the side surfaces of a four-cornered trapezoidal shape. A space for disposing elements such as the bonding wires 9 is provided in the cavity 8 by the inclined surfaces 4f.

The frame 4 has a rectangular opening 4g that penetrates in the vertical direction in the central part of the upper surface part 4b. The opening 4g is formed by four inner side surfaces 4h corresponding to the outer shape of the frame 4 in plan view. The dimensions of the outer shape of the opening 4g in plan view are smaller than the outer shape of the image sensor 3 in plan view. The frame 4 is provided for the image sensor 3 such that the entire pixel region 12 is located within the open range of the opening 4g in plan view. In plan view, the peripheral edge of the image sensor 3 is located on outer sides of the open range of the opening 4g.

The frame 4 is provided on the front surface 2a of the substrate 2 such that the lower surface 4d is positioned further outside the electrodes to which the bonding wires 9 are connected, and is provided so as not to interfere with the bonding wires 9 and the electrodes on the front surface 2a of the substrate 2. The frame 4 is fixed to the front surface 2a of the substrate 2 by a joining part 16 formed from an adhesive such as an epoxy resin-based adhesive or an acrylic resin-based adhesive. In the frame 4, the upper surface 4a is the surface that supports the glass 5.

The glass 5 is an example of a transparent member, and is provided on the image sensor 3 over the frame 4. The glass 5 has a rectangular plate-shaped outer shape and has outer dimensions larger than those of the image sensor 3. The glass 5 has a front surface 5a, which is an upper surface, and a rear surface 5b, which is a lower surface opposite the front surface 5a and facing the image sensor 3.

By providing the glass 5 on the frame 4, the glass 5 is provided parallel to the image sensor 3 at a predetermined space therefrom, on the light-receiving surface side of the image sensor 3. The glass 5 is fixed to the upper surface 4a of the frame 4 by an adhesive such as an ultraviolet (UV)-curable resin, for example. The glass 5 has outer dimensions larger than the opening dimensions of the opening 4g, and is provided on the upper surface part 4b of the frame 4 so as to cover the entire opening 4g from the upper side thereof. In this manner, the glass 5 is provided above the image sensor 3 so as to face the front surface 3a of the image sensor 3 through the opening 4g of the frame 4.

The glass 5 transmits various types of light incident from the front surface 5a side through an optical system such as a lens located thereabove. The light transmitted through the glass 5 reaches the light-receiving surface of the image sensor 3 through the cavity 8. The glass 5 has a function of protecting the light-receiving surface side of the image sensor 3, and along with the frame 4, also has a function of blocking moisture (water vapor), dust, and the like from entering the cavity 8 from the outside. Instead of the glass 5, for example, a plastic plate, a silicon plate that transmits only infrared light, or the like can be used as the transparent member according to the present technique.

In the solid-state image capturing device 1 configured as described above, light transmitted through the glass 5 passes through the cavity 8 and is received and detected by the light-receiving elements constituting the pixels 11 disposed in the pixel region 12 of the image sensor 3.

The solid-state image capturing device 1 configured as described above includes a heat transfer member 20 that has fluid properties, and the space part 7 between the substrate 2 and the image sensor 3 is filled therewith. In other words, the space part 7, which is a sealed space formed by surrounding the gap space between the substrate 2 and the image sensor 3 with the die-bonding material 6, is filled with the heat transfer member 20, which is a thermally-conductive member. Accordingly, the heat transfer member 20 is in full contact with each of the front surface 2a of the substrate 2, the rear surface 3b of the image sensor 3, and the inner surfaces 6b of the die-bonding material 6, which form the space part 7.

The heat transfer member 20 is a heat transfer liquid such as a liquid metal or a Thermal Interface Material (TIM) having a heat dissipation effect that causes heat produced by the image sensor 3, which acts as a heat source, to be conducted to the substrate 2 side. Specifically, an alloy that is liquid at room temperature and contains gallium (Ga), indium (In), and tin (Sn), a silicone-based resin, a thermally-conductive grease, a phase change material, or the like is used as the heat transfer member 20, for example. In addition, a material whose viscosity changes as the temperature changes, such as a material in which the viscosity drops (the fluidity increases) as the temperature rises, may be used as the heat transfer member 20, for example.

An in-substrate cavity part 30 that communicates with the space part 7 is formed in the substrate 2 for the space part 7 filled with the heat transfer member 20 in this manner. In other words, the in-substrate cavity part 30 that receives the heat transfer member 20 by communicating with the space part 7 at one end is formed in the substrate 2.

The in-substrate cavity part 30 receives the heat transfer member 20 exceeding the capacity of the space part 7 while keeping the heat transfer member 20 in a filled state in the space part 7. Accordingly, if the volume of the heat transfer member 20 exceeds the capacity of the space part 7, at least some of the in-substrate cavity part 30 will be occupied by the heat transfer member 20. In this case, an in-space part heat transfer member 20A, which is the part within the space part 7, and an in-substrate heat transfer member 20B, which is the part within the in-substrate cavity part 30, are present as the heat transfer member 20. In the example illustrated in FIG. 1, the in-substrate heat transfer member 20B occupies substantially the entire inner space serving as the in-substrate cavity part 30.

In the present embodiment, a single in-substrate cavity part 30 that forms a channel part communicating with the space part 7 at one end is formed in the substrate 2. The in-substrate cavity part 30 has a channel cross-section (side cross-section) shape that is rectangular, circular, or the like.

The in-substrate cavity part 30 has, at one end, a first opening 31 that is open toward the part of the front surface 2a of the substrate 2 where the space part 7 is formed. The in-substrate cavity part 30 communicates with the space part 7 through the first opening 31. In the example illustrated in FIG. 1, the in-substrate cavity part 30 has the first opening 31 located at a peripheral edge offset from the planar center of the space part 7. However, the position of the part of the in-substrate cavity part 30 that communicates with the space part 7 is not limited.

In addition, the channel-shaped in-substrate cavity part 30 is formed so that the other end thereof is open toward the front surface of the substrate 2, at the outer side of the space part 7. In other words, the in-substrate cavity part 30 has, at the other end, a second opening 32 that is open toward a part of the front surface 2a of the substrate 2 aside from the part where the space part 7 is formed. In the example illustrated in FIG. 1, the in-substrate cavity part 30 has the second opening 32 located at the edge at one side of the substrate 2 (the right side, in FIG. 1). However, the position of the second opening 32 is not limited.

In this manner, the in-substrate cavity part 30 is open at one end toward the front surface 2a of the substrate 2, so as to communicate with the space part 7, through the first opening 31, and at the other end toward the front surface 2a of the substrate 2 at the outside of the space part 7, through the second opening 32.

A blocking part 40 that blocks the other end of the in-substrate cavity part 30 is provided on the front surface 2a side of the substrate 2. In the present embodiment, the blocking part 40 is the joining part 16, on the front surface 2a of the substrate 2, of the frame 4 for supporting the glass 5 provided for the image sensor 3 above the substrate 2.

In other words, the frame 4 serves as a blocking member that blocks the second opening 32 of the in-substrate cavity part 30 from the front surface 2a side of the substrate 2, and the joining part 16 for fixing the frame 4 to the substrate 2 serves as the blocking part 40 and blocks the second opening 32. Accordingly, at the peripheral edge of the front surface 2a of the substrate 2, the in-substrate cavity part 30 is open through the second opening 32 toward a region opposite from the lower surface 4d of the frame 4, and the second opening 32 is blocked by the joining part 16 interposed between the front surface 2a of the substrate 2 and the lower surface 4d of the frame 4.

Note that the second opening 32 of the in-substrate cavity part 30 may be blocked by a dedicated blocking member provided separately, such as a disk-shaped member or the like based on the shape and dimensions of the second opening 32, for example. In this case, the blocking member fixed to the front surface 2a of the substrate 2 by a bonding material such as an adhesive or the like, or a bonding material fixing the blocking member to the substrate 2, serves as the blocking part 40 that blocks the second opening 32. Note that the second opening 32 may also be blocked by applying a bonding material such as an adhesive or the like. In this case, the bonding material that blocks the second opening 32 serves as the blocking part 40.

With respect to the shape of the in-substrate cavity part 30, the in-substrate cavity part 30 is formed so as to be uneven when the substrate 2 is viewed in a side cross-sectional view. Specifically, as illustrated in FIG. 1, the in-substrate cavity part 30 has a first flow channel part 33, which is a flow channel part that forms an end on the first opening 31 side; a second flow channel part 34, which is a flow channel part that forms an end of the second opening 32; and an intermediate flow channel part 35, which is a flow channel part between the first flow channel part 33 and the second flow channel part 34.

The first flow channel part 33 is a flow channel part parallel to the vertical direction, with an upper end thereof serving as the first opening 31 and a lower end thereof communicating with one end (the upstream side) of the intermediate flow channel part 35. The second flow channel part 34 is a flow channel part parallel to the vertical direction, with an upper end thereof serving as the second opening 32 and a lower end thereof communicating with the other end (the downstream side) of the intermediate flow channel part 35.

The intermediate flow channel part 35 has a horizontal upstream-side flow channel part 35a at which the end on the first opening 31 side communicates with the lower end part of the first flow channel part 33, and a horizontal downstream-side flow channel part 35b at which the end on the second opening 32 side communicates with the lower end part of the second flow channel part 34. The intermediate flow channel part 35 is a flow channel part provided with an uneven shape by alternately and repeatedly arranging a vertical flow channel part 35c parallel to the vertical direction, and a horizontal flow channel part 35d parallel to the horizontal direction (parallel to the surface of the substrate 2), from one side of the intermediate flow channel part 35 to the other side of intermediate flow channel part 35, between the upstream-side flow channel part 35a and the downstream-side flow channel part 35b. In such a configuration having the in-substrate cavity part 30, in the example illustrated in FIG. 1, the heat transfer member 20 occupies a range from the first flow channel part 33 communicating with the space part 7 to a position partway along the second flow channel part 34 in the in-substrate cavity part 30.

Note that the shape of the in-substrate cavity part 30 is not particularly limited. For example, in the in-substrate cavity part 30 illustrated in FIG. 1, the length and number of the vertical flow channel part 35c and the horizontal flow channel part 35d are not limited. Additionally, the in-substrate cavity part 30 may be formed such that the other end on the side opposite from the first opening 31 side is located inside the substrate 2, without being open in the front surface 2a of the substrate 2, i.e., without having the second opening 32.

### 2. Method for Manufacturing Semiconductor Device According to First Embodiment

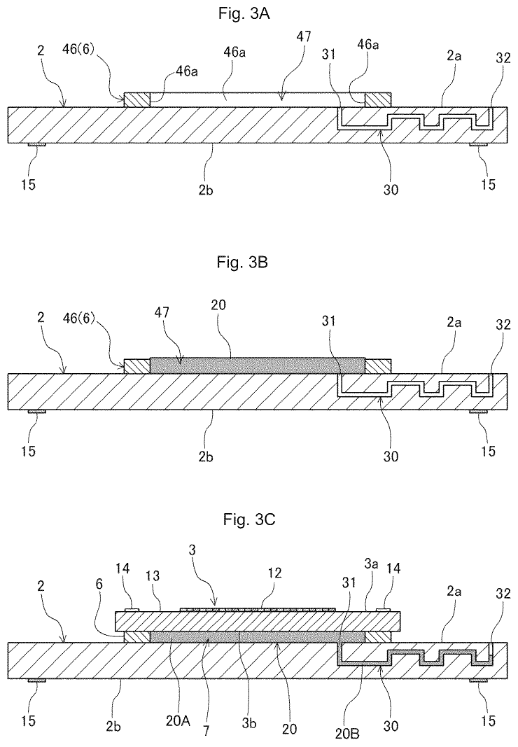

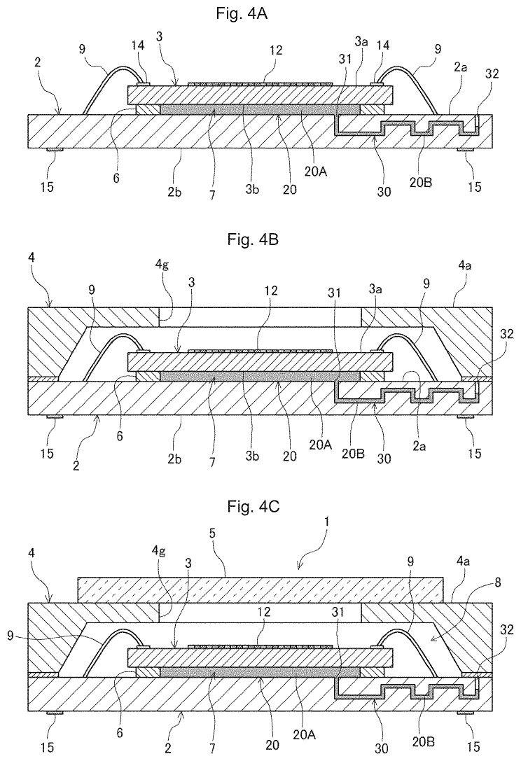

An example of a method for manufacturing the solid-state image capturing device 1 according to the first embodiment of the present technique will be described with reference to FIGS. 3 and 4.

In the method for manufacturing the solid-state image capturing device 1, a step of preparing the substrate 2 having the in-substrate cavity part 30 is performed first, as illustrated in FIG. 3A. The substrate 2 having the in-substrate cavity part 30 can be manufactured through a publicly-known manufacturing method. For example, when the substrate 2 is a ceramic substrate having a multilayer structure in which sheet-shaped members formed of a ceramic material or the like are layered, a manufacturing method such as the following can be used.

A penetrating opening is formed through punching or the like in each sheet-shaped member to be layered, as a part to form the in-substrate cavity part 30. In each sheet-shaped member, the opening is provided such that the in-substrate cavity part 30 having a predetermined shape is formed by the openings in the sheet-shaped members when the plurality of sheet-shaped members constituting the substrate 2 are layered. The substrate 2 having the in-substrate cavity part 30 is formed by layering the sheet-shaped members. In addition, as another method, a method may be used in which, with the sheet-shaped members in a layered state, a part that is to serve as the in-substrate cavity part 30 is formed by a processing device such as a drill.

A low temperature firing layered ceramic substrate called a Low Temperature Co-fired Ceramics (LTCC) substrate, for example, can be given as an example of a ceramic substrate having a multilayer structure. Note that when the substrate 2 is a resin substrate (an organic substrate) having a multilayer structure in which resin sheet-shaped members is layered, the substrate 2 having the in-substrate cavity part 30 can be obtained by using the same manufacturing method as for a ceramic substrate having a multilayer structure. As described above, in the step of preparing the substrate 2, the substrate 2 having the in-substrate cavity part 30, in which one end and the other end are both open toward the front surface 2a side, is obtained. The plurality of terminal electrodes 15 are formed on the rear surface 2b of the substrate 2.

A step of providing the die-bonding material 6 on the substrate 2 having the in-substrate cavity part 30 is performed next, as illustrated in FIG. 3A. The die-bonding material 6 is provided on the substrate 2 so as to have an endless frame shape in plan view. The die-bonding material 6 serves as a support part that forms the space part 7 that, together with the substrate 2 and the image sensor 3 provided on the substrate 2, communicates with the in-substrate cavity part 30 at one end.

In the step of providing the die-bonding material 6, a rib resin 46, which is a resin material that forms the die-bonding material 6, is applied to predetermined parts of the front surface 2a of the substrate 2 using a dispenser or the like, in a rectangular frame shape that follows the outer shape of the substrate 2 in plan view. However, the rib resin 46 may be formed through patterning or the like using photolithography.

By forming the rib resin 46 on the front surface 2a of the substrate 2, a recess 47 that is surrounded by the frame-shaped rib resin 46 and is open on the upper side is formed on the front surface 2a of the substrate 2. The recess 47 is a space on the inner side of the die-bonding material 6 (the rib resin 46) on the front surface 2a side of the substrate 2, and is formed by the part of the front surface 2a of the substrate 2 on the inner side of the rib resin 46, and four inner side surfaces 46a of the rib resin 46.

A step of inserting the heat transfer member 20 having fluid properties into the recess 47 is performed next, as illustrated in FIG. 3B. The recess 47 is filled with the heat transfer member 20 through application using a dispenser or the like, for example.

A step of mounting the image sensor 3 on the rib resin 46 is performed next, as illustrated in FIG. 3C. The chip of the image sensor 3 is set on the rib resin 46 using a chip mounter or the like, and is pressed downward against the rib resin 46 and the heat transfer member 20. As a result, the rib resin 46 contacts the rear surface 3b of the image sensor 3 across the entire periphery thereof and is slightly pressurized by the image sensor 3, and the heat transfer member 20 in the recess 47 flows into the in-substrate cavity part 30 after the capacity of the space part 7 is exceeded.

Here, when a heat transfer member 20 is used in which the viscosity drops as the temperature rises, for example, the flow of the heat transfer member 20 into the in-substrate cavity part 30 can be advanced by heating the heat transfer member 20 to increase the fluidity thereof. Some of the heat transfer member 20 flowing into the in-substrate cavity part 30 forms the in-space part heat transfer member 20A and the in-substrate heat transfer member 20B.

A step of curing the rib resin 46 is then performed according to the material or the like of the rib resin 46. For example, if the rib resin 46 is a thermosetting resin, a heating (curing) process for curing the rib resin 46 is performed. As a result, a configuration is achieved in which the space part 7 formed by the die-bonding material 6 between the substrate 2 and the image sensor 3 is filled with the heat transfer member 20.

In this manner, the step of mounting the image sensor 3 with the heat transfer member 20 inside the recess 47 corresponds to a step of mounting the image sensor 3 on the die-bonding material 6 to form the space part 7 and filling the space part 7 with the heat transfer member 20.

A step of providing the bonding wires 9 that electrically connect the substrate 2 and the image sensor 3 is performed next, as illustrated in FIG. 4A. Here, wire bonding is performed in which the electrodes formed on the front surface 2a of the substrate 2 and the pad electrodes 14 of the image sensor 3 are electrically connected by the bonding wires 9.

A step of providing a frame 4 on the substrate 2 for supporting the glass 5 provided for the image sensor 3 above the substrate 2 is performed next, as illustrated in FIG. 4B. The frame 4 is disposed relative to the substrate 2 such that the lower surface 4d thereof is positioned at the peripheral edge of the front surface 2a of the substrate 2, and is fixed to the substrate 2 by an adhesive such as an epoxy resin-based adhesive or the like. The adhesive is applied to at least one of the frame 4 side or the substrate 2 side over the entire periphery, along the outer shape of the substrate 2.

Through this step, the frame 4 is fixed to the front surface 2a of the substrate 2 over the joining part 16 formed from an adhesive. The joining part 16 seals the second opening 32 of the in-substrate cavity part 30 that was open at the peripheral edge of the front surface 2a of the substrate 2. In this manner, the method for manufacturing the solid-state image capturing device 1 according to the present embodiment includes a step of providing a frame 4 on the substrate 2 as a step of blocking the second opening 32 on the other end of the in-substrate cavity part 30, after the step of filling the space part 7 with the heat transfer member 20.

A step of providing the glass 5 on the frame 4 is then performed, as illustrated in FIG. 4C. The glass 5 is prepared by, for example, cutting a glass sheet having a predetermined shape into a rectangular shape through dicing. The glass 5 is mounted and fixed on the upper surface 4a so as to block the opening 4g of the frame 4 from the upper side, in a state where an adhesive is applied to the predetermined part of the upper surface 4a of the frame 4.

The solid-state image capturing device 1 illustrated in FIGS. 1 and 2 is obtained through the manufacturing method described above.

With the solid-state image capturing device 1 and the manufacturing method thereof according to the present embodiment, the thermal conductivity from the image sensor 3 to the substrate 2 side can be improved, and the cooling efficiency of the image sensor 3 can therefore be improved, which stabilizes the heat dissipation characteristics.

The solid-state image capturing device 1 has a configuration in which the space part 7 formed on the rear surface 3b side of the image sensor 3 above the substrate 2 is filled with the heat transfer member 20. With such a configuration, the heat dissipation performance of the image sensor 3 can be increased by the heat transfer member 20, and the thermal conductivity from the image sensor 3 to the substrate 2 can be increased as compared, for example, to a case where the rear surface 3b side of the image sensor 3 is a cavity. This makes it possible to improve the heat dissipation performance of the solid-state image capturing device 1.

The substrate 2 also has the in-substrate cavity part 30 that communicates with the space part 7. According to such a configuration, the heat transfer member 20 can be prevented from flowing out (leaking) from the outer periphery of the chip of the image sensor 3 to outside the space part 7. This makes it possible, for example, to prevent defects due to the heat transfer member 20 making contact with connection parts of the bonding wires 9 on the front surface 2a of the substrate 2, and stabilize the heat dissipation characteristics by disposing the heat transfer member 20 on the rear surface 3b side of the image sensor 3.

In particular, when the heat transfer member 20 has a relatively low viscosity, the heat transfer member 20 easily leaks from the peripheral edge of the image sensor 3, but providing the in-substrate cavity part 30 that communicates with the space part 7 in the substrate 2 makes it possible to effectively suppress leakage of the heat transfer member 20. This makes it possible to relax limitations on the physical properties of the heat transfer member 20, such as the viscosity of the heat transfer member 20, and makes it possible to expand the options for the material that can be used as the heat transfer member 20.

In addition, because the substrate 2 has the in-substrate cavity part 30, the heat transfer member 20 can escape into the in-substrate cavity part 30, and thus the space part 7 can be reliably filled with the heat transfer member 20 without the heat transfer member 20 leaking from the peripheral edge of the image sensor 3. This makes it possible to reliably improve the thermal conductivity from the image sensor 3 to the substrate 2 side. In addition, because the substrate 2 has the in-substrate cavity part 30, it is easy to adjust the amount of the heat transfer member 20 that enters the recess 47 on the substrate 2 during the manufacture of the solid-state image capturing device 1. The process of manufacturing the solid-state image capturing device 1 can therefore be made more efficient. Note that the in-substrate cavity part 30 can be formed with ease by using a ceramic substrate having a multilayer structure in which sheet-shaped members are layered as the substrate 2.

In addition, the in-substrate cavity part 30 has the second opening 32 on the front surface 2a of the substrate 2 outside the space part 7, and the blocking part 40 is provided over the second opening 32. According to such a configuration, a state in which the in-substrate cavity part 30 communicates with the exterior can be ensured during the process of manufacturing the solid-state image capturing device 1, and thus the heat transfer member 20 can be reliably guided into the in-substrate cavity part 30.

In addition, the blocking part 40 of the second opening 32 of the in-substrate cavity part 30 serves as the joining part 16 of the frame 4 for the substrate 2. According to such a configuration, it is not necessary to provide the blocking part 40 for blocking the second opening 32 of the in-substrate cavity part 30 as a dedicated configuration, and the configuration and manufacturing process of the solid-state image capturing device 1 can therefore be simplified.

In addition, the in-substrate cavity part 30 has a part formed so as to be uneven when the substrate 2 is viewed in a side cross-sectional view. According to such a configuration, foreign substances such as air (bubbles), dust, and the like present with the heat transfer member 20 in the in-substrate cavity part 30 can be suppressed from flowing back to the space part 7 side. This makes it possible to stabilize the state of the heat transfer member 20 disposed on the rear surface 3b side of the image sensor 3, and effectively achieve a heat dissipation effect with the heat transfer member 20.

In addition, the method for manufacturing the solid-state image capturing device 1 uses the substrate 2 on which the in-substrate cavity part 30 having the first opening 31 and the second opening 32 is formed, and includes a step in which, after the space part 7 is filled with the heat transfer member 20, the second opening 32 of the in-substrate cavity part 30 is blocked. This makes it possible to ensure a state of communication between the in-substrate cavity part 30 and the exterior before blocking the second opening 32, and the heat transfer member 20 can therefore be reliably guided into the in-substrate cavity part 30.

In particular, the step of providing the frame 4 on the substrate 2 in the present embodiment is a step of blocking the second opening 32 of the in-substrate cavity part 30. This makes it possible to use an existing step as the step for blocking the second opening 32 of the in-substrate cavity part 30, and the process for manufacturing the solid-state image capturing device 1 can therefore be simplified.

### 3. Variations on Semiconductor Device According to First Embodiment

A variation on the solid-state image capturing device 1 according to the first embodiment will be described next.

### (First Variation)

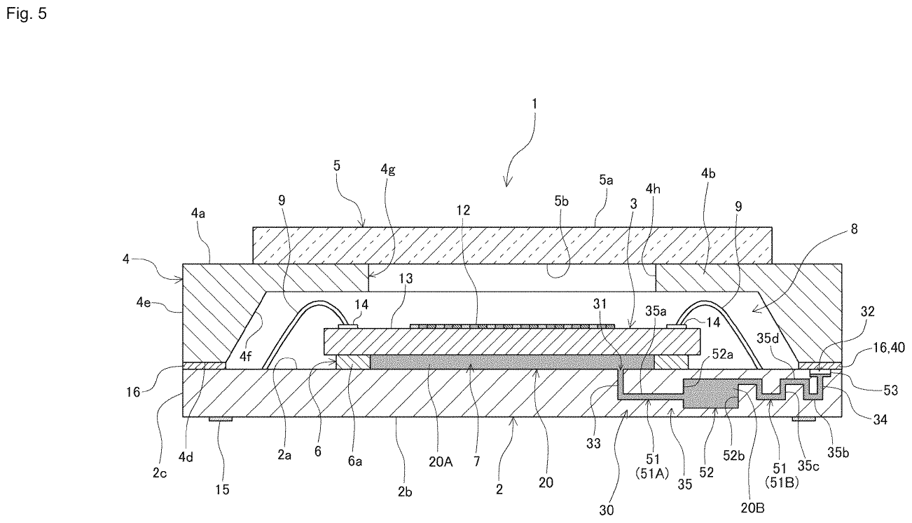

The first variation is a variation on the configuration of the in-substrate cavity part 30. As illustrated in FIG. 5, in the first variation, the in-substrate cavity part 30 has a channel part 51 having a relatively narrow flow channel area, and a containment part 52 that communicates with the channel part 51 and has a larger flow channel area than that of the channel part 51.

Similar to the in-substrate cavity part 30 illustrated in FIG. 1, the channel part 51 is a single channel part in which one end communicates with the space part 7 as the first opening 31, and the other end serves as the second opening 32 blocked by the joining part 16. The containment part 52 is a relatively wide enlarged cavity part provided partway along the channel part 51. By having the containment part 52 partway along the channel part 51, the in-substrate cavity part 30 has, as the channel part 51, a first channel part 51A, which is a part closer to the first opening 31 than the containment part 52, and a second channel part 51B, which is a part closer to the second opening 32 than the containment part 52.

The containment part 52 is formed, for example, as a rectangular space part. The containment part 52 enables a side surface 52a on the first opening 31 side to communicate with the downstream side of the first channel part 51A, and enables a side surface 52b on the second opening 32 side to communicate with the upstream side of the second channel part 51B. However, the shape of the containment part 52 is not particularly limited.

In addition, in the configuration of the first variation, the in-substrate cavity part 30 has an expanded part 53 that is open toward the front surface 2a of the substrate 2, at an end on the second opening 32 side. The expanded part 53 is a part, formed at the upper end of the second flow channel part 34, that expands the flow channel cross-section (planar cross-section) area of the second opening 32 compared to the other flow channel parts in the second flow channel part 34.

In the first variation, the expanded part 53 is a part that expands the opening area of the second opening 32 compared to the flow channel area of the second channel part 51B. The expanded part 53 may be formed as a part in which the diameter of the channel part 51 is expanded, for example, and may be formed as a groove-shaped part that extends in a direction parallel to the front surface 2a of the substrate 2 (e.g., the direction of view in FIG. 5 or the like).

In the example illustrated in FIG. 5, the in-substrate cavity part 30 has the containment part 52 in the intermediate flow channel part 35 between the first flow channel part 33 and the second flow channel part 34, and has the expanded part 53 at the upper end of the second flow channel part 34. In addition, the in-substrate cavity part 30 has a flow channel part that has an uneven shape by alternately and repeatedly arranging the vertical flow channel part 35c and the horizontal flow channel part 35d in a part of the intermediate flow channel part 35 closer to the second opening 32 than the containment part 52. In such a configuration having the in-substrate cavity part 30, in the example illustrated in FIG. 5, the in-substrate cavity part 30 is filled with the heat transfer member 20 from the first flow channel part 33 communicating with the space part 7 to fill the containment part 52, and the heat transfer member 20 occupies a range up to partway along the expanded part 53.

According to the configuration of the first variation, the in-substrate cavity part 30 has the containment part 52, and thus the heat transfer member 20 can be held in the containment part 52. Through this, the heat dissipation effect of the substrate 2 can be improved, and thus the heat dissipation performance of the solid-state image capturing device 1 can be improved. In addition, because the in-substrate cavity part 30 has the containment part 52, foreign substances such as air (bubbles), dust, and the like present with the heat transfer member 20 in the in-substrate cavity part 30 can be effectively suppressed from flowing back to the space part 7 side.

In addition, because the in-substrate cavity part 30 has the expanded part 53, a space for receiving the heat transfer member 20 can be secured on the front surface 2a side of the substrate 2 by using the expanded part 53. This makes it possible to suppress situations where the heat transfer member 20, which has reached the second opening 32 from the space part 7, flows out from the front surface 2a of the substrate 2.

### (Second Variation)

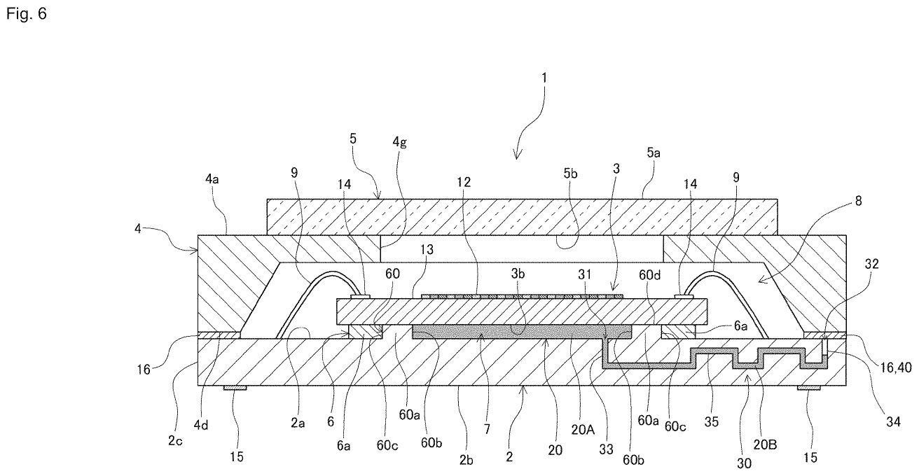

The second variation is a variation on the configuration of the substrate 2. As illustrated in FIG. 6, in the second variation, the substrate 2 has a protrusion 60 that is provided along the inner sides of the die-bonding material 6 and that protrudes from the front surface 2a of the substrate 2.

The protrusion 60 is located on the inner peripheral side of the die-bonding material 6, which has a rectangular frame shape in plan view. The protrusion 60 is provided over the entire periphery along the outer shape of the die-bonding material 6 in plan view, and is formed in an endless shape so as to create a rectangular frame shape in plan view. Accordingly, the protrusion 60 has four side parts 60a that follow corresponding sides of the rectangular frame-shaped outer shape of the die-bonding material 6. The protrusion 60 is provided in a position corresponding to the peripheral region 13 of the image sensor 3 so as to surround the area where the pixel region 12 of the image sensor 3 is formed, in plan view. In addition, the protrusion 60 has a protruding shape that makes the cross-sectional shape of the side parts 60a match the rectangular shape.

The protrusion 60 is located on the inner side of the die-bonding material 6, interposed between the front surface 2a of the substrate 2 and the rear surface 3b of the image sensor 3, and supports the substrate 2 and the image sensor 3 so as to be spaced apart from each other. As a result, together with the front surface 2a of the substrate 2 and the rear surface 3b of the image sensor 3, the protrusion 60 forms, by an inner side surface 60b, the space part 7 between the substrate 2 and the image sensor 3.

An outer surface 60c of the protrusion 60 is in full contact with the die-bonding material 6. In addition, the protrusion 60 has an upper surface 60d, which has a frame shape in plan view and is parallel to the horizontal plane, as a surface of contact with the rear surface 3b of the image sensor 3. The protrusion 60 brings the upper surface 60d into full contact with the rear surface 3b of the image sensor 3.

The protrusion 60 is provided as a part of the substrate 2. For example, when the substrate 2 is a ceramic substrate having a multilayer structure, the protrusion 60 is formed by layering a sheet-shaped member, formed from a ceramic material and having a frame shape in plan view, on the surface that serves as the front surface 2a of the substrate 2. The protrusion 60 may be a part formed by processing the front surface 2a side of the substrate 2 through cutting, etching, or the like.

Note that the protrusion 60 may be provided only partially along the peripheral direction with respect to the outer shape of the die-bonding material 6 in plan view. Specifically, for example, the protrusion 60 may be a part provided as two side parts 60a that follow a pair of the side parts 6a of the frame-shaped die-bonding material 6 that oppose each other in plan view. The protrusion 60 may be a part provided intermittently (partially) in the peripheral direction with respect to the inner peripheral side of the frame-shaped die-bonding material 6 in plan view.

The protrusion 60 is not limited to a part provided as a part of the substrate 2, and may be a part provided by fixing a separate member to the substrate 2. Specifically, the protrusion 60 may be a part provided by fixing a frame-shaped member constituted by ceramics such as glass, an inorganic material such as metal or silicon, or the like to the front surface 2a of the substrate 2 using an adhesive or the like, for example. In addition, the position at which the protrusion 60 is provided on the rear side of the image sensor 3 is not particularly limited.

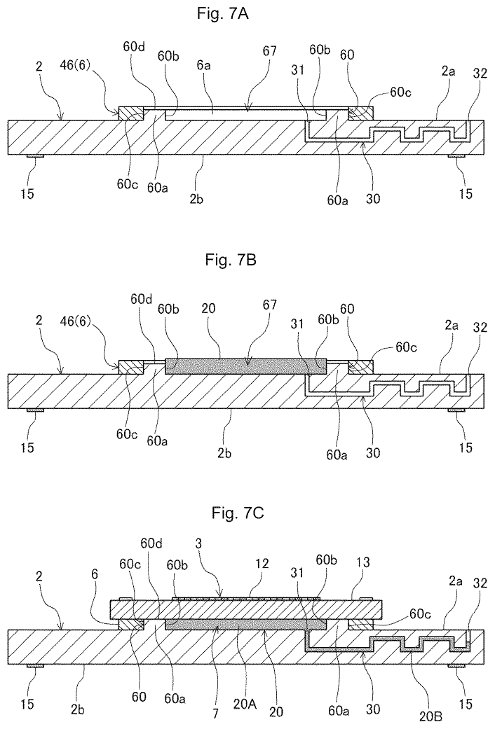

In the process of manufacturing the solid-state image capturing device 1 of the second variation, as illustrated in FIG. 7A, when applying the rib resin 46 using a dispenser or the like, the rib resin 46 that will serve as the die-bonding material 6 is applied so as to completely cover the outer surface 60c of the protrusion 60.

In the configuration in which the substrate 2 has the protrusion 60, a recess 67 that is surrounded by the frame-shaped protrusion 60 and is open on the upper side is formed on the front surface 2a of the substrate 2 as a space that receives the heat transfer member 20. The recess 67 is a space on the inner side of the protrusion 60 on the front surface 2a side of the substrate 2, and is formed by the part of the front surface 2a of the substrate 2 on the inner side of the protrusion 60 and the four inner side surfaces 60b of the protrusion 60.

A step of inserting the heat transfer member 20 into the recess 67 is performed after the rib resin 46 is applied, as illustrated in FIG. 7B.

A step of mounting the image sensor 3 on the rib resin 46 and the protrusion 60 is performed thereafter, as illustrated in FIG. 7C. Here, the chip of the image sensor 3 is set on the rib resin 46 using a chip mounter or the like, and is pressed downward against the rib resin 46, the protrusion 60, and the heat transfer member 20.

As a result, the rib resin 46 is slightly pressurized by the image sensor 3, the rear surface 3b of the image sensor 3 makes contact with the upper surface 60d of the protrusion 60, and part of the heat transfer member 20 in the recess 67 flows into the in-substrate cavity part 30. Here, some of the rib resin 46 may enter between the rear surface 3b of the image sensor 3 and the upper surface 60d of the protrusion 60.

A step of curing the rib resin 46 is then performed according to the material or the like of the rib resin 46. As a result, a configuration is achieved in which the space part 7 formed by the die-bonding material 6 and the protrusion 60 between the substrate 2 and the image sensor 3 is filled with the heat transfer member 20.

In this manner, the step of mounting the image sensor 3 with the heat transfer member 20 inside the recess 67 corresponds to a step of mounting the image sensor 3 on the die-bonding material 6 to form the space part 7 and filling the space part 7 with the heat transfer member 20. The subsequent steps are as described with reference to the figures in FIG. 4.

According to the configuration of the second variation, in addition to the in-substrate cavity part 30 suppressing leakage of the heat transfer member 20 from the chip outer periphery of the image sensor 3, the protrusion 60 present on the inner sides of the die-bonding material 6 can directly suppress leakage of the heat transfer member 20 from the chip outer periphery of the image sensor 3. In other words, according to the configuration of the second variation, the die-bonding material 6 and the protrusion 60 serve as a double barrier for the space part 7, and leakage of the heat transfer member 20 to the outer peripheral sides of the image sensor 3 can be effectively suppressed. Thus, from the standpoint of preventing leakage of the heat transfer member 20, the protrusion 60 is preferably formed in an endless shape so as to form a rectangular frame shape in plan view.

In addition, according to the configuration in which the substrate 2 has the protrusion 60, the protrusion 60 can be used as a stopper for the image sensor 3 by bringing the protrusion 60 into contact with the image sensor 3 in the step of mounting the image sensor 3 on the substrate 2. This makes it possible to easily and reliably position the image sensor 3 with respect to the substrate 2 in the vertical direction. As a result, it is easy to adjust the amount of the heat transfer member 20 that enters the recess 67 on the substrate 2.

The protrusion 60 can be provided precisely and easily by providing the protrusion 60 as a part of the substrate 2. This makes it possible to effectively suppress leakage of the heat transfer member 20 and improve the efficiency of the process of manufacturing the solid-state image capturing device 1, as compared to when the protrusion 60 is provided as a member separate from the substrate 2.

### (Third Variation)

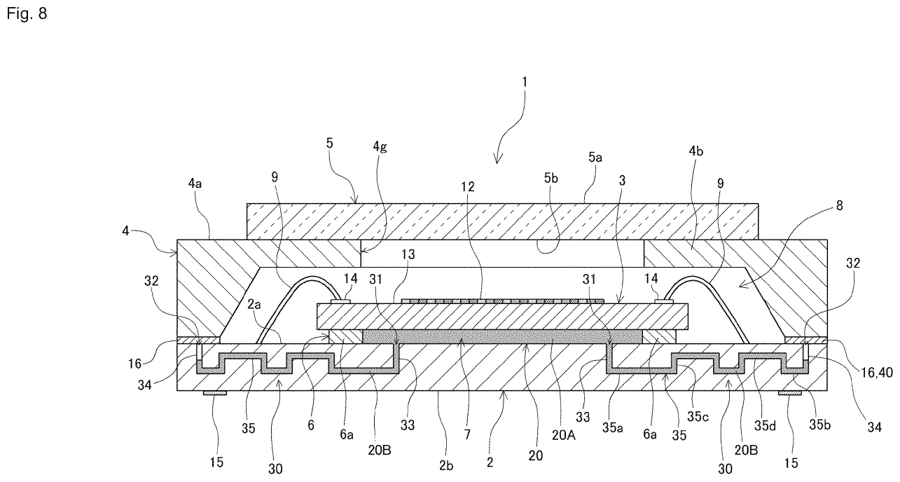

As illustrated in FIG. 8, in a third variation, a plurality of in-substrate cavity parts 30 are formed in the substrate 2. In the example illustrated in FIG. 8, two of the in-substrate cavity parts 30 are formed symmetrically on the left and right sides. The configuration may have a total of four of the in-substrate cavity parts 30 by also forming two of the in-substrate cavity parts 30 in the same arrangement as that illustrated in FIG. 8 in a direction orthogonal to the left-right direction in FIG. 8 in plan view.

In this manner, a plurality of the in-substrate cavity parts 30 may be formed in the substrate 2. In addition, the in-substrate cavity parts 30 may branch the first opening 31 side or the second opening 32 side into a plurality of flow channels. In other words, the in-substrate cavity part 30 may have a plurality of at least one of the first opening 31 and the second opening 32.

According to the configuration of the third variation, the amount of the heat transfer member 20 received by the in-substrate cavity part 30 can be increased, and the heat transfer member 20 present in the substrate 2 can be dispersed. Through this, the heat dissipation effect of the substrate 2 can be achieved efficiently, and thus the heat dissipation performance of the solid-state image capturing device 1 can be improved. In addition, because the amount of the heat transfer member 20 received by the in-substrate cavity part 30 is increased, it is easy to adjust the amount of the heat transfer member 20 that enters the recess 67 on the substrate 2 during the manufacture of the solid-state image capturing device 1.

In addition, by providing a plurality of the in-substrate cavity parts 30 in the substrate 2, the parts that form the in-substrate cavity parts 30 can be dispersed, which makes it possible to even out the strength of the substrate 2. In other words, defects such as imbalances in the strength of the substrate 2, distortion in the substrate 2, and the like, which arise when the in-substrate cavity part 30 is formed in only one location in the substrate 2, can be suppressed by providing a plurality of the in-substrate cavity parts 30. From the standpoint of evening the strength of the substrate 2, the plurality of in-substrate cavity parts 30 are preferably formed symmetrically, with linear symmetry or point symmetry, for example.

### 4. Example of Configuration of Semiconductor Device According to Second Embodiment

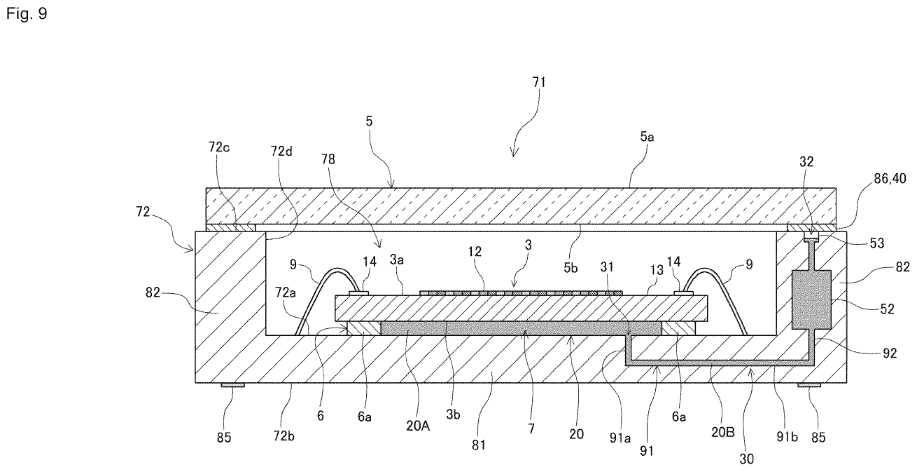

An example of the configuration of a solid-state image capturing device 71 according to a second embodiment of the present technique will be described with reference to FIG. 9. In the embodiments described below, configurations common to or corresponding to those in the first embodiment will be given the same names or reference signs, and descriptions of identical matters will be omitted as appropriate.

As illustrated in FIG. 9, the solid-state image capturing device 71 according to the present embodiment includes a cavity substrate 72 as a substrate according to the present technique. In other words, the solid-state image capturing device 71 includes the cavity substrate 72, the image sensor 3, and the glass 5, and has a package structure in which the image sensor 3 is mounted within the cavity substrate 72, the glass 5 is mounted on the cavity substrate 72, and the inner space of the cavity substrate 72 is a sealed cavity 78.

The cavity substrate 72 is a package substrate having a rectangular plate-shaped flat plate part 81, and four wall parts 82 formed in a rectangular frame shape following the edges of the flat plate part 81 in plan view. The cavity substrate 72 is constituted by the flat plate part 81 and the four wall parts 82, forming a box shape with the upper side as an open side. In other words, in the cavity substrate 72, the four wall parts 82 form, on the upper side of the flat plate part 81, a concave space part with the upper side as an opening side.

In the flat plate part 81, the cavity substrate 72 has a front surface 72a, which is one plate surface on which the image sensor 3 is mounted, and a rear surface 72b, which is the plate surface on the side opposite from the front surface 72a. The image sensor 3 is die-bonded to the front surface 72a of the cavity substrate 72 by the die-bonding material 6. Note that a thickness direction of the flat plate part 81 is the vertical direction of the solid-state image capturing device 71, the front surface 72a side is an upper side, and the rear surface 72b side is a lower side. The cavity substrate 72 takes the upper surfaces of the four wall parts 82 as an upper surface 72c, which forms a rectangular frame shape in plan view and is parallel to the horizontal plane.

The cavity substrate 72 is a circuit substrate on which predetermined circuitry is formed, and like the substrate 2 of the first embodiment, is a ceramic substrate having a multilayer structure in which sheet-shaped members formed of a ceramic material or the like are layered. However, the cavity substrate 72 may be another type of substrate, such as an organic substrate using, as a base material, an organic material such as a glass epoxy resin, which is a type of fiber-reinforced plastic. The cavity substrate 72 may also be constituted by, for example, a dividing element that takes the position of the front surface 72a in the vertical direction as a vertical division position. In this case, the cavity substrate 72 has a structure in which a rectangular plate-shaped part serving as the flat plate part 81 and a square column part forming the wall parts 82 are joined in an integrated manner.

The die-bonding material 6 is partially interposed between the front surface 72a of the cavity substrate 72 and the rear surface 3b of the image sensor 3, and by bonding the flat plate part 81 and the image sensor 3 with those parts spaced apart from each other, the gap-shaped space part 7, which is a sealed space, is formed between the flat plate part 81 and the image sensor 3.

The cavity substrate 72 and the image sensor 3 are electrically connected by the plurality of bonding wires 9. Each of the bonding wires 9 is connected at one end to an electrode (not shown) formed on the front surface 72a of the cavity substrate 72, and at the other end to a pad electrode 14 of the image sensor 3, thereby electrically connecting these electrodes to each other. The electrodes of the cavity substrate 72 to which the bonding wires 9 are connected are electrically connected to a plurality of terminal electrodes 85 formed on the rear surface 72b side of the cavity substrate 72 through a predetermined wiring part formed within the cavity substrate 72.

The glass 5 is fixed to and supported by the wall parts 82 of the cavity substrate 72. The glass 5 is fixed to the upper surface 72c of the cavity substrate 72 by a joining part 86 formed from an adhesive. The periphery of the cavity 78 is sealed by the joining part 86.

By providing the glass 5 on the wall parts 82, the glass 5 is provided parallel to the image sensor 3 at a predetermined space therefrom, on the light-receiving surface side of the image sensor 3. The glass 5 is provided so as to cover, from above, the entirety of an upper opening 72d formed by the four wall parts 82. Accordingly, the glass 5 has outer dimensions larger than the opening dimensions of the opening 72d. The glass 5 has outer dimensions slightly smaller than the outer shape of the cavity substrate 72 in plan view, and is located within a range of the outer shape of the cavity substrate 72 in plan view.

In the solid-state image capturing device 71 configured as described above, the space part 7 between the flat plate part 81 of the cavity substrate 72 and the image sensor 3 is filled with the heat transfer member 20. The in-substrate cavity part 30 that communicates with the space part 7 is formed in the cavity substrate 72.

The in-substrate cavity part 30 communicates with the space part 7 through the first opening 31 on one end. In addition, in the in-substrate cavity part 30, the second opening 32 on the other end is open toward the upper surface 72c of one of the wall parts 82 (on the right side, in FIG. 9).

The in-substrate cavity part 30 is formed in the cavity substrate 72 from the flat plate part 81 to the wall part 82. In other words, the in-substrate cavity part 30 has a flat plate part formation flow channel part 91, which is a part formed in the flat plate part 81, and a wall part formation flow channel part 92, which is a part formed in the wall part 82. The flat plate part formation flow channel part 91 is a flow channel part formed mainly in a lateral direction (the horizontal direction), and the wall part formation flow channel part 92 is a flow channel part formed mainly in a longitudinal direction (vertical direction).

Specifically, as illustrated in FIG. 9, the flat plate part formation flow channel part 91 has a vertical flow channel part 91a, which is a flow channel part parallel to the vertical direction and which has the first opening 31 on an upper end, and a horizontal flow channel part 91b, which forms a right angle with the vertical flow channel part 91a. The wall part formation flow channel part 92 is formed as a vertical flow channel part, which is a flow channel part parallel to the vertical direction and which has the second opening 32 on an upper end. The downstream side of the horizontal flow channel part 91b of the flat plate part formation flow channel part 91 communicates with the lower end part of the wall part formation flow channel part 92.

In the example illustrated in FIG. 9, in the wall part formation flow channel part 92, the containment part 52 having a flow channel area larger than the other flow channel parts (channel parts) of the wall part formation flow channel part 92 is formed in an intermediate part in the vertical direction. The containment part 52 is a relatively wide enlarged cavity part provided partway along the wall part formation flow channel part 92.

Additionally, the expanded part 53 that is open toward the upper surface 72c of the cavity substrate 72 is formed at the upper end part of the wall part formation flow channel part 92. The expanded part 53 is a part that expands the opening area of the second opening 32 compared to the flow channel area of the other flow channel parts of the wall part formation flow channel part 92. The expanded part 53 may be formed as a part in which the diameter of the wall part formation flow channel part 92 is greater than other parts, for example, and may be formed as a groove-shaped part that extends in a direction parallel to the upper surface 72c of the cavity substrate 72 (e.g., the direction of view in FIG. 9 or the like).

Note that the shape of the in-substrate cavity part 30 is not particularly limited. For example, in the configuration illustrated in FIG. 9, the flat plate part formation flow channel part 91 may be formed with the flow channel part having an uneven shape in a side cross-sectional view of the cavity substrate 72.

The blocking part 40 that blocks the other end of the in-substrate cavity part 30 is provided on the upper surface 72c side, which is the front surface side of the cavity substrate 72. In the present embodiment, the blocking part 40 is the joining part 86 that joins the glass 5 provided for the image sensor 3 to the upper surface 72c of the cavity substrate 72.

In other words, the glass 5 serves as a blocking member that blocks the second opening 32 of the in-substrate cavity part 30 from the upper surface 72c side of the cavity substrate 72, and the joining part 86 for fixing the glass 5 to the cavity substrate 72 serves as the blocking part 40 and blocks the second opening 32. Accordingly, in the in-substrate cavity part 30, in the upper surface 72c of the cavity substrate 72, the second opening 32 is open toward a region opposite from the rear surface 5b of the glass 5, and the second opening 32 is blocked by the joining part 86 interposed between the upper surface 72c of the cavity substrate 72 and the rear surface 5b of the glass 5. Note that the second opening 32 of the in-substrate cavity part 30 may be blocked by a blocking member provided separately, as in the first embodiment.

### 5. Method for Manufacturing Semiconductor Device According to Second Embodiment

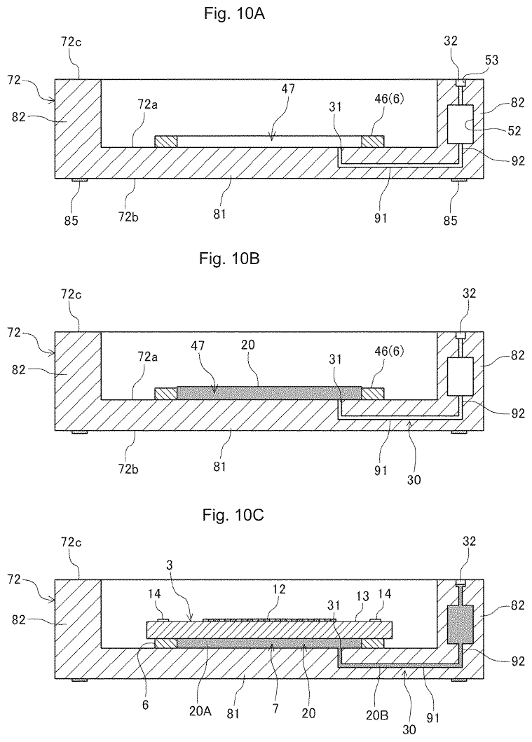

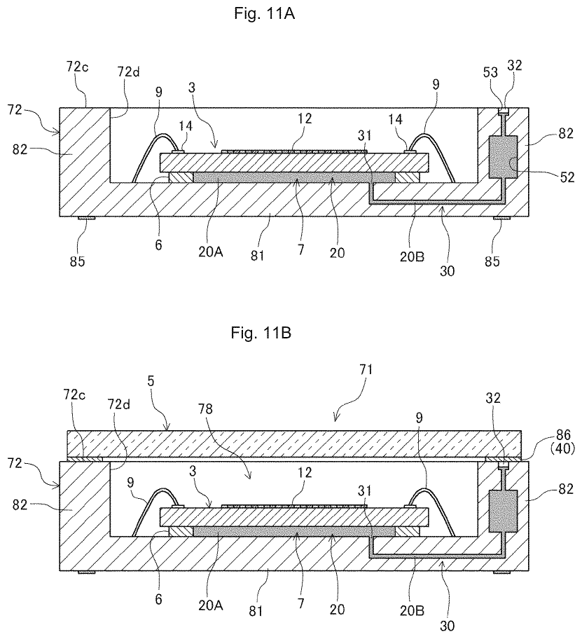

An example of a method for manufacturing the solid-state image capturing device 71 according to the second embodiment of the present technique will be described with reference to FIGS. 10 and 11.

First, a step of providing the die-bonding material 6 on the cavity substrate 72 having the in-substrate cavity part 30 is performed next, as illustrated in FIG. 10A. The die-bonding material 6 is provided on the cavity substrate 72 so as to have an endless frame shape in plan view. The die-bonding material 6 serves as a support part that forms the space part 7 that, together with the cavity substrate 72 and the image sensor 3 provided on the cavity substrate 72, communicates with the in-substrate cavity part 30 at one end.

In the step of providing the die-bonding material 6, the rib resin 46, which is a resin material that forms the die-bonding material 6, is applied to predetermined parts of the front surface 72a of the cavity substrate 72, in a rectangular frame shape that follows the outer shape of the cavity substrate 72 in plan view. The recess 47 is formed on the front surface 72a of the cavity substrate 72 as a result.

A step of inserting the heat transfer member 20 into the recess 47 is performed next, as illustrated in FIG. 10B.

A step of mounting the image sensor 3 on the rib resin 46 is performed next, as illustrated in FIG. 10C. Here, the chip of the image sensor 3 is pressed downward against the rib resin 46 and the heat transfer member 20. As a result, an amount of the heat transfer member 20 exceeding the capacity of the space part 7 flows into the in-substrate cavity part 30. Then, a step of curing the rib resin 46 is performed, resulting in the configuration in which the space part 7 formed by the die-bonding material 6 between the cavity substrate 72 and the image sensor 3 is filled with the heat transfer member 20.

A step of providing the bonding wires 9 that electrically connect the cavity substrate 72 and the image sensor 3 is performed next, as illustrated in FIG. 11A.

A step of providing the glass 5, which is provided for the image sensor 3, on the cavity substrate 72 is then performed, as illustrated in FIG. 11B. The glass 5 is mounted on the upper surface 72c and fixed by an adhesive so as to block the opening 72d of the cavity substrate 72 from the upper side. The adhesive is applied to at least one of the cavity substrate 72 side or the glass 5 side over the entire periphery along the outer shape of the glass 5.

Through this step, the glass 5 is fixed to the upper surface 72c of the cavity substrate 72 over the joining part 86, which is formed from an adhesive. The joining part 86 seals the second opening 32 of the in-substrate cavity part 30 that was open at the peripheral edge of the upper surface 72c of the cavity substrate 72. In this manner, the method for manufacturing the solid-state image capturing device 71 according to the present embodiment includes a step of providing the glass 5 on the cavity substrate 72 as a step of blocking the second opening 32 on the other end of the in-substrate cavity part 30, after the step of filling the space part 7 with the heat transfer member 20.

The solid-state image capturing device 71 illustrated in FIG. 9 is obtained through the manufacturing method described above.

Similar to the first embodiment, with the solid-state image capturing device 71 and the manufacturing method thereof according to the present embodiment, the thermal conductivity from the image sensor 3 to the cavity substrate 72 side can be improved, and the cooling efficiency of the image sensor 3 can therefore be improved, which stabilizes the heat dissipation characteristics. Additionally, providing the in-substrate cavity part 30 in the cavity substrate 72 makes it possible to achieve the same effects as in the first embodiment.

In particular, in the present embodiment, the part where the in-substrate cavity part 30 is formed can be enlarged by the cavity substrate 72 having the wall part 82 provided on the upper side of the flat plate part 81. This makes it possible to increase the amount of the heat transfer member 20 received by the in-substrate cavity part 30, and thus the heat dissipation performance of the solid-state image capturing device 71 can be improved. In addition, because the amount of the heat transfer member 20 received by the in-substrate cavity part 30 is increased, it is easy to adjust the amount of the heat transfer member 20 that enters the recess 47 on the cavity substrate 72 during the manufacture of the solid-state image capturing device 71.

In addition, in the solid-state image capturing device 71, the in-substrate cavity part 30 has the containment part 52 and the expanded part 53, and thus the effects provided by the containment part 52 and the expanded part 53 can be achieved in the same manner as in the first embodiment. Note that the in-substrate cavity part 30 extending from the flat plate part 81 to the wall part 82 can be formed with ease by using a ceramic substrate having a multilayer structure in which sheet-shaped members are layered as the cavity substrate 72.

In addition, the blocking part 40 provided for the second opening 32 of the in-substrate cavity part 30 serves as the joining part 86 for joining the glass 5 to the cavity substrate 72. According to such a configuration, it is not necessary to provide the blocking part 40 for blocking the second opening 32 of the in-substrate cavity part 30 as a dedicated configuration, and the configuration and manufacturing process of the solid-state image capturing device 71 can therefore be simplified.

In the method for manufacturing the solid-state image capturing device 71, the step of providing the glass 5 on the cavity substrate 72 serves as a step of blocking the second opening 32 of the in-substrate cavity part 30. This makes it possible to use an existing step as the step for blocking the second opening 32 of the in-substrate cavity part 30, and the process for manufacturing the solid-state image capturing device 71 can therefore be simplified.

### 6. Example of Configuration of Semiconductor Device According to Third Embodiment

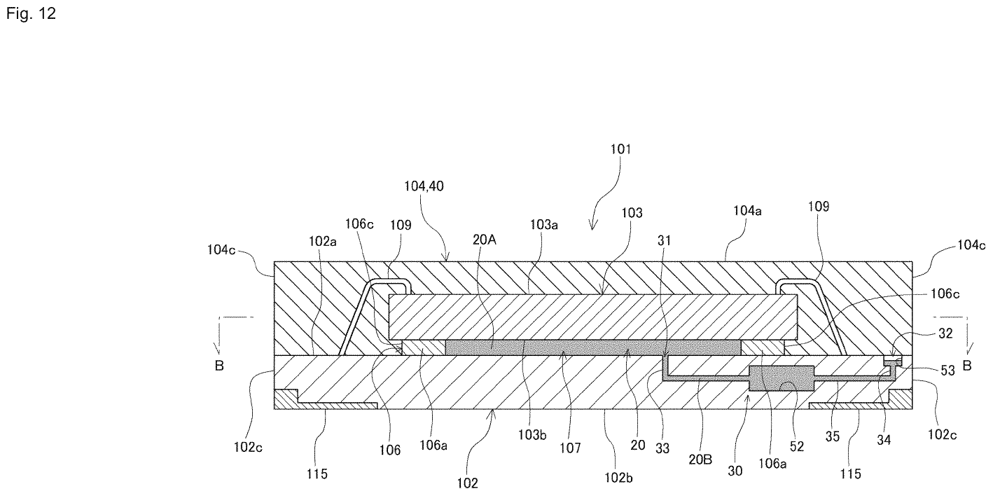

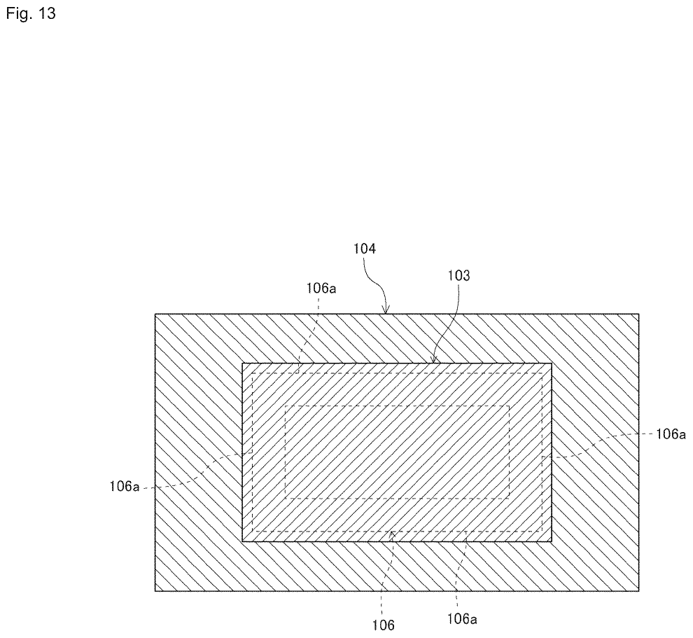

An example of the configuration of a semiconductor device 101 according to a third embodiment of the present technique will be described with reference to FIGS. 12 and 13. FIG. 13 is a cross-sectional view of a position B-B in FIG. 12, with some of the configurations omitted.

As illustrated in FIGS. 12 and 13, the semiconductor device 101 according to the present embodiment includes a substrate 102, an IC chip 103 provided on the substrate 102 as a semiconductor element, and a sealing resin part 104 formed in the periphery of the IC chip 103 on the substrate 102.

The IC chip 103 is affixed to the substrate 102 by a die-bonding material 106, such as an insulative or conductive adhesive. In other words, the semiconductor device 101 includes the die-bonding material 106 that supports the IC chip 103 on the substrate 102. The die-bonding material 106 is a support part that, together with the substrate 102 and the IC chip 103, forms a space part 107.

The substrate 102 is a flat plate-shaped member having a rectangular outer shape. The substrate 102 has a front surface 102a, which is a surface on which the IC chip 103 is mounted; a rear surface 102b, which is the surface on the side opposite the front surface 102a; and four side surfaces 102c. The IC chip 103 is die-bonded to the front surface 102a of the substrate 102 by the die-bonding material 106. In other words, the die-bonding material 106 provided on the front surface 102a of the substrate 102 supports the IC chip 103 so as to face the front surface 102a while being parallel to the substrate 102.

The substrate 102 is a circuit substrate on which predetermined circuitry is formed, and like the substrate 2 of the first embodiment, is, for example, a ceramic substrate having a multilayer structure in which sheet-shaped members formed of a ceramic material or the like are layered.

The IC chip 103 is a rectangular plate-shaped semiconductor chip having a predetermined circuit structure. The IC chip 103 is, for example, a logic IC such as a Central Processing Unit (CPU) or a memory IC such as a Dynamic Random Access Memory (DRAM).

The die-bonding material 106 has the same configuration as the die-bonding material 6 according to the first embodiment, and is interposed between the front surface 102a of the substrate 102 and a rear surface 103b of the IC chip 103. By bonding the substrate 102 and the IC chip 103 so as to be spaced apart from each other, the gap-shaped space part 107, which is a sealed space, is formed between the substrate 102 and the IC chip 103.

The die-bonding material 106 is formed in an endless shape over the entire periphery of the peripheral edge of the IC chip 103 so as to create a rectangular frame shape in plan view, along the outer shape of the IC chip 103 in plan view. Accordingly, the die-bonding material 106 has four side parts 106a following corresponding sides of the rectangular outer shape of the IC chip 103.

The substrate 102 and the IC chip 103 are electrically connected by a plurality of bonding wires 109. Each of the bonding wires 109 is connected at one end to an electrode (not shown) formed on the front surface 102a of the substrate 102, and at the other end to an electrode (not shown) formed on a front surface 103a of the IC chip 103, thereby electrically connecting these electrodes to each other. The electrodes of the substrate 102 to which the bonding wires 109 are connected are electrically connected to a plurality of terminal electrodes 115 formed on the rear surface 102b of the substrate 102 through a predetermined wiring part formed within the substrate 102.

The sealing resin part 104 is a resin part that forms a seal by completely covering the entire periphery of the die-bonding material 106 and the IC chip 103 from above on the substrate 102. The bonding wires 9 and the connections at both ends thereof are completely covered by the sealing resin part 104. Specifically, the sealing resin part 104 covers the entirety of the parts of the front surface 102a of the substrate 102 outside the die-bonding material 6, the front surface 103a and four side surfaces 103c of the IC chip 103, and an outer side surface 106c of the die-bonding material 106, with the bonding wires 9 completely embedded therein.

The sealing resin part 104 has a rectangular plate-shaped outer shape that follows the rectangular outer shape of the substrate 102 in plan view, and is formed as a layer part on the substrate 102 in which the IC chip 103 or the like is embedded. The sealing resin part 104 has a flat upper surface 104a, and four side surface parts 104c that are contiguous and flush with the side surfaces 102c of the substrate 102.

The sealing resin part 104 is formed by taking the configuration in which the IC chip 103 is mounted on the substrate 102 and connected thereto by the bonding wires 9, and curing a resin material in the periphery of the IC chip 103 on the substrate 102. The sealing resin part 104 is formed in a predetermined shape by injection molding using a metal mold, for example. However, the sealing resin part 104 may be a part formed through potting using a dispenser, for example. In this case, the sealing resin part 104 is formed by ejecting the resin material to serve as the sealing resin part 104 from a nozzle of the dispenser to apply the resin material to a predetermined part, and then curing the resin material.

The material of the sealing resin part 104 is, for example, a thermosetting resin that contains silicon oxide as a principal component, and contains alumina or the like as a filler. For example, a thermosetting resin such as a phenolic resin, a silicone resin, an acrylic resin, an epoxy resin, a urethane resin, a silicon resin, or a polyether amide resin; a thermoplastic resin such as polyamide-imide, polypropylene, or a liquid crystal polymer; a photosensitive resin such as a UV-curable resin, which is an acrylic resin; rubber; and other publicly-known resin materials can be used alone or in combination as the resin material that forms the sealing resin part 104. Note that the sealing resin part 104 is insulative.

In the semiconductor device 101 configured as described above, the space part 107 between the substrate 102 and the IC chip 103 is filled with the heat transfer member 20. The in-substrate cavity part 30 that communicates with the space part 107 is formed in the substrate 102.

The in-substrate cavity part 30 communicates with the space part 107 through the first opening 31 on one end. In addition, the in-substrate cavity part 30 is open toward the front surface 102a of the substrate 102 on the outer side of the space part 107, through the second opening 32 on the other end. In the example illustrated in FIG. 12, the in-substrate cavity part 30 has the second opening 32 located at the edge at one side of the substrate 102 (the right side, in FIG. 12).

In the example illustrated in FIG. 12, the in-substrate cavity part 30 has the first flow channel part 33 and the second flow channel part 34 parallel to the vertical direction, and the intermediate flow channel part 35 parallel to the horizontal direction. Additionally, the containment part 52 having a flow channel area larger than the other flow channel parts (channel parts) of the intermediate flow channel part 35 is formed in an intermediate part of the intermediate flow channel part 35. Additionally, the expanded part 53 that is open toward the front surface 102a of the substrate 102 is formed at the upper end part of the second flow channel part 34.

The blocking part 40 that blocks the other end of the in-substrate cavity part 30 is provided on the front surface 102a side of the substrate 102. In the present embodiment, the blocking part 40 serves as the sealing resin part 104 formed on the substrate 102. Note that the second opening 32 of the in-substrate cavity part 30 may be blocked by a blocking member provided separately, as in the first embodiment.

### 7. Method for Manufacturing Semiconductor Device According to Third Embodiment

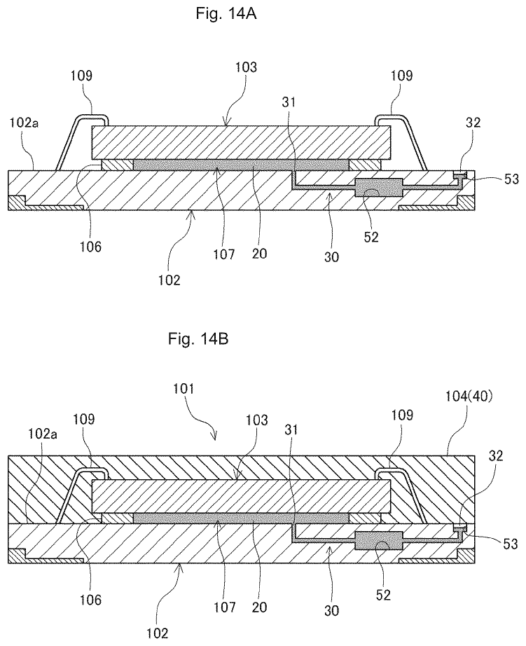

An example of a method for manufacturing the semiconductor device 101 according to the third embodiment of the present technique will be described with reference to FIG. 14.

To obtain the configuration illustrated in FIG. 14A, steps such as those described hereinafter are performed in the same manner as in the first embodiment. In other words, after the rib resin serving as the die-bonding material 106 is applied to the front surface 102a of the substrate 102 that includes the in-substrate cavity part 30, the heat transfer member 20 is inserted into the recess formed by the rib resin. The IC chip 103 is then mounted on the rib resin so as to press against the rib resin and the heat transfer member 20, and some of the heat transfer member 20 flows into the in-substrate cavity part 30. Wire bonding which disposes the bonding wires 109 between the substrate 102 and the IC chip 103 is then performed.

A step of providing the sealing resin part 104 in the periphery of the IC chip 103 on the substrate 102 is performed next, as illustrated in FIG. 14B. The sealing resin part 104 is formed using a mold for molding molded resin parts, for example.

The mold for forming the sealing resin part 104 is, for example, a transfer mold having an upper mold and a lower mold that, together with the upper mold, forms a cavity serving as a molding space. A workpiece that is to accept the formation of the sealing resin part 104 is set in the mold. Note that the workpiece is provided with the configuration illustrated in FIG. 14A.

After the workpiece is set in the mold, the mold is put into a tightened state, and the cavity is formed as the workpiece is clamped. After that, a resin material in a melted state is injected into the cavity, which is filled, and the resin material is then cured by subjecting the resin material to a predetermined treatment such as heating or cooling. A resin part that serves as the sealing resin part 104 is formed as a result. Thereafter, the clamping of the mold is released, the mold is opened, and the workpiece that has undergone injection molding is removed.

In the process of forming the sealing resin part 104, the workpiece set in the mold may be divided into a chip-shaped piece corresponding to the semiconductor device 101, or may be a workpiece in which a plurality of the IC chips 103 are provided on a single substrate sheet formed as a collection of substrates 102. If the workpiece set in the mold is formed using a substrate sheet, a dicing process is performed on the workpiece removed from the mold after the injection molding, to cut out and divide the workpiece into predetermined regions corresponding to the semiconductor device 101.

By forming the sealing resin part 104 on the substrate 102, the sealing resin part 104 seals the second opening 32 of the in-substrate cavity part 30 that was open at the peripheral edge of the front surface 102a of the substrate 102. In this manner, the method for manufacturing the semiconductor device 101 according to the present embodiment includes a step of providing the sealing resin part 104 on the substrate 2 as a step of blocking the second opening 32 on the other end of the in-substrate cavity part 30, after the step of filling the space part 107 with the heat transfer member 20.

The semiconductor device 101 illustrated in FIGS. 12 and 13 is obtained through the manufacturing method described above.

Similar to the first embodiment, with the semiconductor device 101 and the manufacturing method thereof according to the present embodiment, the thermal conductivity from the IC chip 103 to the substrate 102 side can be improved, and the cooling efficiency of the IC chip 103 can therefore be improved, which stabilizes the heat dissipation characteristics. Additionally, providing the in-substrate cavity part 30 in the substrate 102 makes it possible to achieve the same effects as in the first embodiment.

In addition, the blocking part 40 provided for the second opening 32 of the in-substrate cavity part 30 serves as the sealing resin part 104 provided on the substrate 102. According to such a configuration, it is not necessary to provide the blocking part 40 for blocking the second opening 32 of the in-substrate cavity part 30 as a dedicated configuration, and the configuration and manufacturing process of the semiconductor device 101 can therefore be simplified.

In the method for manufacturing the semiconductor device 101, the step of providing the sealing resin part 104 on the substrate 102 is a step of blocking the second opening 32 of the in-substrate cavity part 30. This makes it possible to use an existing step as the step for blocking the second opening 32 of the in-substrate cavity part 30, and the process for manufacturing the semiconductor device 101 can therefore be simplified.

### 8. Example of Configuration of Semiconductor Device According to Fourth Embodiment

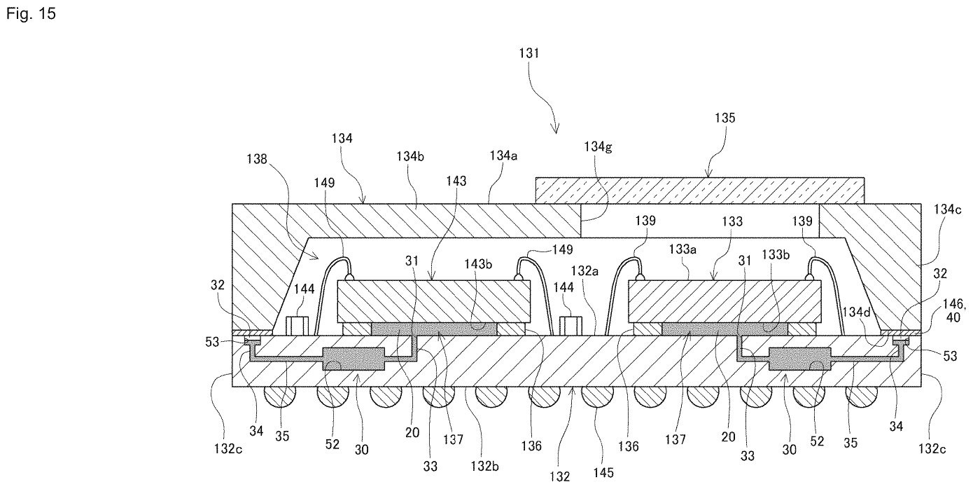

An example of the configuration of a semiconductor device according to a fourth embodiment of the present technique will be described with reference to FIG. 15. The semiconductor device according to the present embodiment is a light-emitting device 131.

Together with, for example, an image capturing device including an image sensor or the like, the light-emitting device 131 constitutes a ranging device. In the ranging device, a subject is irradiated with light emitted from the light-emitting device 131, which functions as a light source, after which the light reflected by the subject is received by the image capturing device and an image of the subject is captured. An image signal output from the image capturing device is used by a control unit or the like of the ranging device to measure (calculate) the distance to the subject.

As illustrated in FIG. 15, the light-emitting device 131 includes a substrate 132, as well as a Vertical Cavity Surface Emitting Laser (VCSEL) 133 and a Laser Diode Driver (LDD) 143 provided on the substrate 132 as semiconductor elements. In other words, the light-emitting device 131 includes two semiconductor elements, namely the VCSEL 133 and the LDD 143. The light-emitting device 131 also includes a frame 134 as a support member provided on the substrate 132, and a glass 135 provided on the frame 134.

The VCSEL 133 and the LDD 143 are affixed to the substrate 132 by a die-bonding material 136, such as an insulative or conductive adhesive. In other words, the light-emitting device 131 includes the die-bonding material 136, which supports both the VCSEL 133 and the LDD 143 on the substrate 132. The die-bonding material 136 is a support part that, together with the substrate 132 and the VCSEL 133 or the LDD 143, forms space parts 137.

The light-emitting device 131 has a package structure in which the glass 135 is mounted on the substrate 132 over the frame 134, and a cavity 138 is formed on the substrate 132. The glass 135 is provided parallel with the VCSEL 133 above the VCSEL 133, and the cavity 138, which is a sealed space, is formed by the frame 134 and the glass 135 together with the substrate 132, above the substrate 132.

The substrate 132 is a flat plate-shaped member having a rectangular outer shape. The substrate 132 has a front surface 132a, which is a surface on which the VCSEL 133 and the LDD 143 are mounted; a rear surface 132b, which is the surface on the side opposite the front surface 132a; and four side surfaces 132c. The VCSEL 133 and the LDD 143 are die-bonded to the front surface 132a of the substrate 132 by the die-bonding material 136. In other words, the die-bonding material 136 provided on the front surface 132a of the substrate 132 supports the VCSEL 133 and the LDD 143 so as to face the front surface 132a while being parallel to the substrate 132.

The substrate 132 is a circuit substrate on which predetermined circuitry is formed, and like the substrate 2 of the first embodiment, is, for example, a ceramic substrate having a multilayer structure in which sheet-shaped members formed of a ceramic material or the like are layered.

The VCSEL 133 is, for example, a rectangular plate-shaped element chip, and is a light-emitting element that emits laser light for irradiating the subject. The VCSEL 133 has a plurality of light-emitting elements having a VCSEL structure and disposed in a two-dimensional array, and an upper surface 133a side is a light emission surface side. The VCSEL 133 is electrically connected to the substrate 132 by a plurality of bonding wires 139.

The LDD 143 is, for example, a rectangular plate-shaped element chip, and has a drive circuit that drives the VCSEL 133. The LDD 143 drives the VCSEL 133 using a power supply voltage generated by a power supply circuit (not shown). The LDD 143 is electrically connected to the substrate 132 by a plurality of bonding wires 149.

The die-bonding material 136 has the same configuration as the die-bonding material 6 according to the first embodiment, and is interposed between the front surface 132a of the substrate 132 and rear surfaces 133b and 143b of the VCSEL 133 and the LDD 143, respectively. By bonding the substrate 132 to the VCSEL 133 and the LDD 143 so as to be spaced apart from each other, the gap-shaped space parts 137, which are sealed spaces, are formed between the substrate 132 and the VCSEL 133, and between the substrate 132 and the LDD 143. The die-bonding material 136 is formed in an endless shape over the entire peripheries of the peripheral edges of the VCSEL 133 and the LDD 143 so as to create rectangular frame shapes in plan view, along the outer shapes of the VCSEL 133 and the LDD 143 in plan view.

In the substrate 132, the electrodes to which the bonding wires 139 are connected are electrically connected to a plurality of external terminals 145 formed on the rear surface 132b of the substrate 132 through a predetermined wiring part formed within the substrate 132. In the example illustrated in FIG. 15, the plurality of external terminals 145 form a BGA using solder balls. A plurality of passive components 144, such as capacitors and resistors, are mounted in predetermined positions on the front surface 132a of the substrate 132.

The frame 134 has the same configuration as the frame 4 according to the first embodiment, and is provided to surround the VCSEL 133 and the LDD 143 on the front surface 132a side of the substrate 132. The frame 134 is a rectangular or square-shaped frame-shaped member, and has approximately the same outer dimensions as the outer shape of the substrate 132 in plan view. The frame 134 has a plate-shaped upper surface part 134b that forms a horizontal upper surface 134a serving as a surface that supports the glass 135, and a peripheral wall part 134c formed on the lower side of the upper surface part 134b to form a horizontal lower surface 134d.

The frame 134 has a rectangular opening 134g that penetrates in the vertical direction in a part of the upper surface part 134b above the VCSEL 133. The frame 134 is fixed to the front surface 132a of the substrate 132 by a joining part 146 formed from an adhesive, with the lower surface 134d positioned at the peripheral edge of the front surface 132a of the substrate 132.

The glass 135 is an example of a transparent member, and is provided on the VCSEL 133 over the frame 134. The glass 135 has a rectangular plate-shaped outer shape and has outer dimensions larger than those of the VCSEL 133.

By providing the glass 135 on the frame 134, the glass 135 is provided parallel to the VCSEL 133 at a predetermined space therefrom, on the light-emitting surface side of the VCSEL 133. The glass 135 is arranged to cover the entire opening 134g of the frame 134 from the upper side, and is fixed to the upper surface 134a of the frame 134 by an adhesive or the like.

In the light-emitting device 131 configured as described above, the space parts 137 between the substrate 132 and the VCSEL 133, and between the substrate 132 and the LDD 143, are filled with the heat transfer member 20. The in-substrate cavity part 30 that communicates with each of the space parts 137 is formed in the substrate 132. In other words, the light-emitting device 131 is provided with an independent in-substrate cavity part 30 for each of the semiconductor elements, namely the VCSEL 133 and the LDD 143.

In the example illustrated in FIG. 15, the in-substrate cavity parts 30 provided for the VCSEL 133 and the LDD 143 have the same configuration as the in-substrate cavity part 30 according to the third embodiment and illustrated in FIG. 12, and thus the same reference signs are assigned thereto, and descriptions thereof will be omitted.

The blocking part 40 that blocks the other end of the in-substrate cavity part 30 is provided on the front surface 132a side of the substrate 132. Similar to the first embodiment, in the present embodiment, the blocking part 40 serves as the joining part 146 that joins the frame 134, which is for supporting the glass 135 provided for the VCSEL 133 on the substrate 132, to the front surface 132a of the substrate 132. Accordingly, the method for manufacturing the light-emitting device 131 includes a step of providing the frame 134 on the substrate 132 as a step of blocking the second opening 32 on the other end of the in-substrate cavity part 30, after the step of filling the space parts 137 for the VCSEL 133 and the LDD 143 with the heat transfer member 20.

Similar to the first embodiment, with the light-emitting device 131 and the manufacturing method thereof according to the present embodiment, the thermal conductivity from the VCSEL 133 and the LDD 143 to the substrate 132 side can be improved, and the cooling efficiency of the VCSEL 133 and the LDD 143 can therefore be improved, which stabilizes the heat dissipation characteristics. Additionally, providing the in-substrate cavity part 30 in the substrate 132 makes it possible to achieve the same effects as in the first embodiment.

In addition, the blocking part 40 provided for the second opening 32 of the in-substrate cavity part 30 serves as the joining part 146 for joining the frame 134 to the substrate 132, and the configuration and manufacturing process of the light-emitting device 131 can therefore be simplified.

### 9. Example of Configuration of Electronic Device

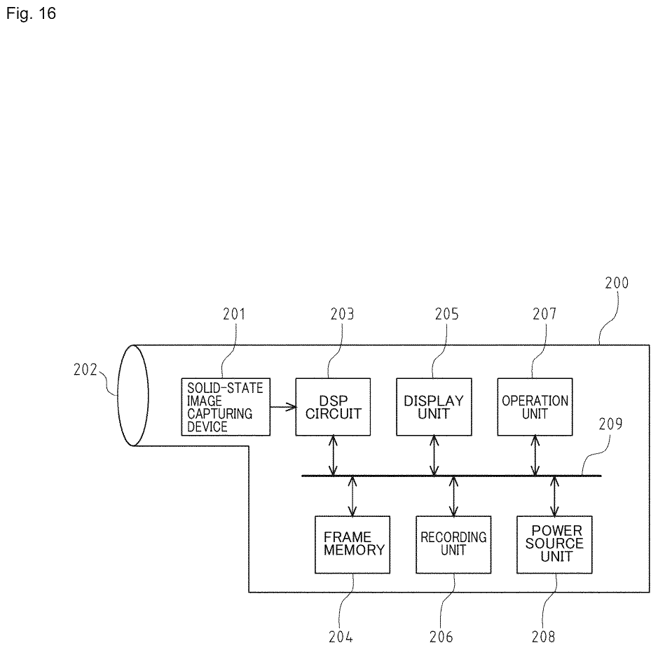

An example of the application of the semiconductor device according to the above-described embodiments to an electronic device will be described with reference to FIG. 16.

The semiconductor device (solid-state image capturing device) according to the present technique can be applied to a general electronic device in which a solid-state image sensor is used in an image capturing unit (a photoelectric conversion unit), e.g., a camera device such as a digital still camera or a video camera, a mobile terminal device that has an image capturing function, a copier in which a solid-state image sensor is used in an image reading unit, or the like. The solid-state image capturing device may be formed as a single chip, or may be formed as a module having an image capturing function, in which an image capturing unit and a signal processing unit or an optical system packaged together.

As illustrated in FIG. 16, a camera device 200 serving as an electronic device includes an optical unit 202, a solid-state image capturing device 201, a digital signal processor (DSP) circuit 203 serving as a camera signal processing circuit, a frame memory 204, a display unit 205, a recording unit 206, an operation unit 207, and a power source unit 208. The DSP circuit 203, the frame memory 204, the display unit 205, the recording unit 206, the operation unit 207, and the power source unit 208 are connected to one another as appropriate by a connection line 209 such as a bus line. The solid-state image capturing device 201 is, for example, the solid-state image capturing device 1 according to the first embodiment described above.

The optical unit 202 includes a plurality of lenses, and captures incident light (image light) from a subject and forms an image on an imaging surface of the solid-state image capturing device 201. The solid-state image capturing device 201 converts the amount of incident light, with which an image is formed on the imaging surface by the optical unit 202, into an electrical signal in units of pixels, and outputs the electrical signal as a pixel signal.

The display unit 205 includes, for example, a panel-type display device such as a liquid crystal panel or an organic Electro Luminescence (EL) panel, and displays moving images or still images captured by the solid-state image capturing device 201. The recording unit 206 records the moving images or the still images captured by the solid-state image capturing device 201 in a recording medium such as a hard disk or a semiconductor memory.

The operation unit 207 issues operation commands for various functions of the camera device 200 in response to operations by a user. The power source unit 208 appropriately supplies various types of power serving as operation power for the DSP circuit 203, the frame memory 204, the display unit 205, the recording unit 206, and the operation unit 207, to those units.

According to such a camera device 200, with respect to the solid-state image capturing device 201, the thermal conductivity from the image sensor 3 to the substrate 2 side can be improved, and the cooling efficiency of the image sensor 3 can therefore be improved, which stabilizes the heat dissipation characteristics.

The descriptions of the foregoing embodiments are merely examples of the present technique, and the present technique is not intended to be limited to the embodiments. Therefore, it goes without saying that various changes aside from the foregoing embodiments can be made according to the design and the like, without departing from the technical spirit of the present disclosure. Furthermore, the effects described in the present disclosure are merely exemplary and not intended to be limiting, and other effects may be provided as well. Furthermore, the configurations described in the foregoing embodiments can be combined as appropriate.

In the foregoing embodiments, the semiconductor element is the image sensor 3, the IC chip 103, the VCSEL 133, and the LDD 143, but the semiconductor element according to the present technique is not limited thereto.

Note that the present technique can also take on the following configurations.

(1)

A semiconductor device including:
a substrate;
a semiconductor element provided on the substrate; and
a heat transfer member that has fluidity and that fills a space part between the substrate and the semiconductor element,
wherein one or more in-substrate cavity parts that communicate with the space part at one end and receive the heat transfer member are formed in the substrate.
   (2)

The semiconductor device according to (1),
wherein the in-substrate cavity part is formed such that an other end is open toward a surface of the substrate, and
a blocking part that blocks the other end of the in-substrate cavity part is provided on a surface side of the substrate.
   (3)

The semiconductor device according to (2),
wherein the blocking part is a support member for supporting a transparent member provided for the semiconductor element on the substrate, or a joining part that joins the transparent member to the surface of the substrate.
   (4)

The semiconductor device according to (2), further including:
a sealing resin part formed on the substrate in a periphery of the semiconductor element,
wherein the blocking part is the sealing resin part.
   (5)

The semiconductor device according to any one of (1) to (4),
wherein the in-substrate cavity part has a channel part having a relatively small flow channel area, and a containment part that communicates with the channel part and has a larger flow channel area than the channel part.
   (6)

The semiconductor device according to any one of (1) to (5),
wherein the in-substrate cavity part is formed having an uneven shape when the substrate is viewed in a side cross-sectional view.
   (7)

The semiconductor device according to any one of (1) to (6),
wherein the in-substrate cavity part has an expanded part that is open toward the surface of the substrate at an end part of the other end.
   (8)

The semiconductor device according to any one of (1) to (7), further including:
a support part that supports the semiconductor element on the substrate and forms the space part together with the substrate and the semiconductor element,
wherein the substrate has a protrusion that is provided along an inner side of the support part and that protrudes from the surface of the substrate.
   (9)

The semiconductor device according to (8),
wherein the protrusion is provided as a part of the substrate.
   (10)

An electronic device including a semiconductor device, the semiconductor device including:
a substrate;
a semiconductor element provided on the substrate; and
a heat transfer member that has fluidity and that fills a space part between the substrate and the semiconductor element,
wherein one or more in-substrate cavity parts that communicate with the space part at one end and receive the heat transfer member are formed in the substrate.
   (11)

A method for manufacturing a semiconductor device, the method including:
providing, on a substrate having an in-substrate cavity part that has one end and an other end open toward a surface side, a die-bonding material serving as a support part that, together with the substrate and the semiconductor element provided on the substrate, forms a space part that communicates with the one end of the in-substrate cavity part, the die-bonding material having an endless shape in plan view;
inserting a heat transfer member having fluidity into a space within the die-bonding material on the surface side of the substrate; and
forming the space part by mounting the semiconductor element on the die-bonding material, and filling the space part with the heat transfer member.
   (12)

The method for manufacturing the semiconductor device according to (11), further including:
blocking an opening on the other end of the in-substrate cavity part after the filling of the heat transfer member.
   (13)

The method for manufacturing the semiconductor device according to (12),
wherein the blocking of the opening on the other end is providing, on the substrate, a transparent member provided for the semiconductor element or a support member that supports the transparent member on the substrate.
   (14)

The method for manufacturing the semiconductor device according to (12),
wherein the blocking of the opening on the other end is providing a sealing resin part in a periphery of the semiconductor element on the substrate.

### REFERENCE SIGNS LIST

1 Solid-state image capturing device (semiconductor device)
2 Substrate
2a Front surface
3 Image sensor (semiconductor element)
4 Frame (support member)
5 Glass (transparent member)
6 Die-bonding material (support part)
7 Space part
16 Joining part (blocking part)
20 Heat transfer member
30 In-substrate cavity part
31 First opening
32 Second opening
35 Intermediate flow channel part
35c Vertical flow channel part
35d Horizontal flow channel part
40 Blocking part
51 Channel part
52 Containment part
53 Expanded part
60 Protrusion
71 Solid-state image capturing device
72 Cavity substrate
86 Joining part (blocking part)
101 Semiconductor device
102 Substrate
103 IC chip (semiconductor element)
104 Sealing resin part
106 Die-bonding material (support part)
107 Space part
131 Light-emitting device (semiconductor device)
132 Substrate
133 VCSEL (semiconductor element)
134 Frame (support member)
135 Glass (transparent member)
136 Die-bonding material (support part)
137 Space part
143 LDD (semiconductor element)
200 Camera device (electronic device)
201 Solid-state image capturing device (semiconductor device)

1. A semiconductor device comprising:
a substrate;
a semiconductor element provided on the substrate; and
a heat transfer member that has fluidity and that fills a space part between the substrate and the semiconductor element,
wherein one or more in-substrate cavity parts that communicate with the space part at one end and receive the heat transfer member are formed in the substrate.

2. The semiconductor device according to claim 1,
wherein the in-substrate cavity part is formed such that an other end is open toward a surface of the substrate, and
a blocking part that blocks the other end of the in-substrate cavity part is provided on a surface side of the substrate.

3. The semiconductor device according to claim 2,
wherein the blocking part is a support member for supporting a transparent member provided for the semiconductor element on the substrate, or a joining part that joins the transparent member to the surface of the substrate.

4. The semiconductor device according to claim 2, further comprising:
a sealing resin part formed on the substrate in a periphery of the semiconductor element,
wherein the blocking part is the sealing resin part.

5. The semiconductor device according to claim 1,
wherein the in-substrate cavity part has a channel part having a relatively small flow channel area, and a containment part that communicates with the channel part and has a larger flow channel area than the channel part.

6. The semiconductor device according to claim 1,
wherein the in-substrate cavity part is formed having an uneven shape when the substrate is viewed in a side cross-sectional view.

7. The semiconductor device according to claim 1,
wherein the in-substrate cavity part has an expanded part that is open toward the surface of the substrate at an end part of the other end.

8. The semiconductor device according to claim 1, further comprising:
a support part that supports the semiconductor element on the substrate and forms the space part together with the substrate and the semiconductor element,
wherein the substrate has a protrusion that is provided along an inner side of the support part and that protrudes from the surface of the substrate.

9. The semiconductor device according to claim 8,
wherein the protrusion is provided as a part of the substrate.

10. An electronic device comprising a semiconductor device, the semiconductor device including:
a substrate;
a semiconductor element provided on the substrate; and
a heat transfer member that has fluidity and that fills a space part between the substrate and the semiconductor element,
wherein one or more in-substrate cavity parts that communicate with the space part at one end and receive the heat transfer member are formed in the substrate.

11. A method for manufacturing a semiconductor device, the method comprising:
providing, on a substrate having an in-substrate cavity part that has one end and an other end open toward a surface side, a die-bonding material serving as a support part that, together with the substrate and the semiconductor element provided on the substrate, forms a space part that communicates with the one end of the in-substrate cavity part, the die-bonding material having an endless shape in plan view;
inserting a heat transfer member having fluidity into a space within the die-bonding material on the surface side of the substrate; and
forming the space part by mounting the semiconductor element on the die-bonding material, and filling the space part with the heat transfer member.

12. The method for manufacturing a semiconductor device according to claim 11, further comprising:
blocking an opening on the other end of the in-substrate cavity part after the filling of the heat transfer member.

13. The method for manufacturing a semiconductor device according to claim 12,
wherein the blocking of the opening on the other end is providing, on the substrate, a transparent member provided for the semiconductor element or a support member that supports the transparent member on the substrate.

14. The method for manufacturing a semiconductor device according to claim 12,
wherein the blocking of the opening on the other end is providing a sealing resin part in a periphery of the semiconductor element on the substrate.
